(19) United States
(12) Patent Application Publication
(10) Pub. No.: US 2024/0250639 A1
(43) Pub. Date: Jul. 25, 2024

(54) Solar Panels having an Integral and Internal Metal Foil, Mounted on a Support Substrate with Embedded Wires

(71) Applicant: SOLARPAINT LTD., YOKNEAM ILLIT (IL)

(72) Inventors: Eran Maimon, Kibbutz Nahsholim (IL); Omri Gover, Tel Aviv (IL); Yaron Tidhar, Even Yehuda (IL); Haggai Manor, Beit Lehem HaGlilit (IL); Hod Yarkoni, Tel Aviv (IL); Ramon Joseph Albalak, Haifa (IL)

(21) Appl. No.: 18/582,685

(22) Filed: Feb. 21, 2024

Related U.S. Application Data
(63) Continuation of application No. PCT/IL2022/050941, filed on Aug. 29, 2022.
(63) Continuation-in-part of application No. 18/129,865, filed on Apr. 2, 2023.
Application No. 18/129,865 is a continuation of application No. PCT/IL2021/051202, filed on Oct. 7, 2021.
Application No. PCT/IL2021/051202 is a continuation-in-part of application No. 17/353,867, filed on Jun. 22, 2021, now Pat. No. 11,978,815.
Application No. 18/129,865 is a continuation-in-part of application No. 17/353,867, filed on Jun. 22, 2021, now Pat. No. 11,978,815.
(63) Continuation-in-part of application No. 17/353,867, filed on Jun. 22, 2021, now Pat. No. 11,978,815.
Application No. 18/129,865 is a continuation-in-part of application No. 17/802,335, filed on Aug. 25, 2022.
(63) Continuation-in-part of application No. 18/372,720, filed on Sep. 26, 2023.
Application No. 18/372,720 is a continuation of application No. PCT/IL2022/050339, filed on Mar. 29, 2022.
Application No. PCT/IL2022/050339 is a continuation-in-part of application No. PCT/IL2021/051202, filed on Oct. 8, 2021.
Application No. PCT/IL2021/051202 is a continuation-in-part of application No. PCT/IL2021/051269, filed on Oct. 27, 2021.
Application No. PCT/IL2021/051269 is a continuation-in-part of application No. PCT/IL2022/050030, filed on Jan. 10, 2022.
Application No. PCT/IL2022/050030 is a continuation-in-part of application No. 17/353,867, filed on Jun. 22, 2021, now Pat. No. 11,978,815.
Application No. 18/372,720 is a continuation-in-part of application No. 18/136,359, filed on Apr. 19, 2023.
Application No. 18/136,359 is a continuation of application No. PCT/IL2021/051269, filed on Oct. 27, 2021.
Application No. PCT/IL2021/051269 is a continuation-in-part of application No. 17/353,867, filed on Jun. 22, 2021, now Pat. No. 11,978,815.
Application No. 18/372,720 is a continuation-in-part of application No. 18/217,620, filed on Jul. 3, 2023.
Application No. 18/217,620 is a continuation of application No. PCT/IL2022/050030, filed on Jan. 10, 2022.
Application No. PCT/IL2022/050030 is a continuation-in-part of application No. 17/802,335, filed on Aug. 25, 2022.
Application No. 18/372,720 is a continuation-in-part of application No. 18/129,865, filed on Apr. 2, 2023.
Application No. 18/129,865 is a continuation-in-part of application No. PCT/IL2021/051202, filed on Oct. 7, 2021.
Application No. PCT/IL2021/051202 is a continuation-in-part of application No. 17/353,867, filed on Jun. 22, 2021, now Pat. No. 11,978,815.
Application No. 18/136,359 is a continuation-in-part of application No. 17/802,335, filed on Aug. 25, 2022.
Application No. PCT/IL2022/050030 is a continuation-in-part of application No. 17/353,867, filed on Jun. 22, 2021, now Pat. No. 11,978,815.
Application No. 17/353,867 is a continuation-in-part of application No. PCT/IL2021/051269, filed on Oct. 27, 2021.
Application No. PCT/IL2021/051269 is a continuation-in-part of application No. PCT/IL2021/051202, filed on Oct. 7, 2021.
Application No. 18/217,620 is a continuation-in-part of application No. 17/353,867, filed on Jun. 22, 2021, now Pat. No. 11,978,815.
Application No. 17/353,867 is a continuation-in-part of application No. 16/362,665, filed on Mar. 24, 2019, now Pat. No. 11,081,606.
Application No. 17/353,867 is a continuation-in-part of application No. PCT/IL2019/051416, filed on Dec. 26, 2019.
Application No. PCT/IL2019/051416 is a continuation-in-part of application No. 16/362,665, filed on Mar. 24, 2019, now Pat. No. 11,081,606.
Application No. PCT/IL2022/050030 is a continuation-in-part of application No. 17/802,335, filed on Aug. 25, 2022.
Application No. 18/217,620 is a continuation-in-part of application No. 18/129,865, filed on Apr. 2, 2023.
Application No. 18/129,865 is a continuation of application No. PCT/IL2021/051202, filed on Oct. 7, 2021.
Application No. PCT/IL2021/051202 is a continuation-in-part of application No. 17/353,867, filed on Jun. 22, 2021, now Pat. No. 11,978,815.
Application No. 18/217,620 is a continuation-in-part of application No. 18/136,359, filed on Apr. 19, 2023.
Application No. 18/136,359 is a continuation of application No. PCT/IL2021/051269, filed on Oct. 27, 2021.
Application No. PCT/IL2021/051269 is a continuation-in-part of application No. 17/353,867, filed on Jun. 22, 2021, now Pat. No. 11,978,815.
(63) Continuation-in-part of application No. 18/442,127, filed on Feb. 15, 2024.
Application No. 18/442,127 is a continuation of application No. PCT/IL2022/050899, filed on Aug. 18, 2022.
(60) Provisional application No. 63/238,802, filed on Aug. 31, 2021.
(60) Provisional application No. 63/238,803, filed on Aug. 31, 2021.
(60) Provisional application No. 63/238,810, filed on Aug. 31, 2021.
(60) Provisional application No. 63/088,535, filed on Oct. 7, 2020.
(60) Provisional application No. 63/167,660, filed on Mar. 30, 2021.
(60) Provisional application No. 63/106,666, filed on Oct. 28, 2020.
(60) Provisional application No. 63/088,535, filed on Oct. 7, 2020.
(60) Provisional application No. 62/785,282, filed on Dec. 27, 2018.
(60) Provisional application No. 62/785,282, filed on Dec. 27, 2018.
(60) Provisional application No. 63/088,535, filed on Oct. 7, 2020.
(60) Provisional application No. 63/106,666, filed on Oct. 28, 2020.
(60) Provisional application No. 63/234,727, filed on Aug. 19, 2021.
(60) Provisional application No. 63/238,808, filed on Aug. 31, 2021.
(60) Provisional application No. 63/239,969, filed on Sep. 2, 2021.

(51) Int. Cl. H02S 40/36; H01L 31/048; H01L 31/05; H05K 1/03

(52) U.S. Cl. CPC H02S 40/36; H01L 31/048; H01L 31/0512; H01L 31/0516; H05K 1/032

(57) ABSTRACT

A flexible solar module has an integral and internal thin metal foil, which is an integral layer of the solar cell stack. The thin metal foil collects and transports photovoltaic (PV) generated electric power from a plurality of regions of the solar module. A single metal foil can mechanically connect, and can collect PV-generated electric power, from multiple such solar cells; and is further coated from beneath by lamination or encapsulation layers. A plurality of solar modules are mounted on top of a support structure or a polymeric support substrate, that has metal wires running integrally therein. The metal wires are arranged in accordance with a pre-defined layout, such that most of the length of each metal wire is concealed and is protected within the support structure or the polymeric support substrate. An ending of each metal wire protrudes from the support structure or the polymeric support substrate, at a particular location that is configured to match an intended location of an electrical terminal of a PV module that is intended to be mounted on top of the support structure or the polymeric support substrate.

### CROSS-REFERENCE TO RELATED APPLICATIONS

This patent application is a Continuation of PCT international application number PCT/IL2022/050941, having an international filing date of Aug. 29, 2022, which is hereby incorporated by reference in its entirety.

The above-mentioned PCT/IL2022/050941 claims priority and benefit: from U.S. 63/238,802, filed on Aug. 31, 2021, which is hereby incorporated by reference in its entirety; and from U.S. 63/238,803, filed on Aug. 31, 2021, which is hereby incorporated by reference in its entirety; and from U.S. 63/238,810, filed on Aug. 31, 2021, which is hereby incorporated by reference in its entirety.

This patent application is also a Continuation-in-Part (CIP) of, and claims benefit and/or priority from: patent application U.S. Ser. No. 18/129,865, filed on Apr. 2, 2023, which is hereby incorporated by reference in its entirety.

The above-mentioned U.S. Ser. No. 18/129,865 is a Continuation of PCT international patent application number PCT/IL2021/051202, having an international filing date of Oct. 7, 2021, which is hereby incorporated by reference in its entirety.

The above-mentioned PCT/IL2021/051202 claims priority and benefit: (i) from U.S. 63/088,535, filed on Oct. 7, 2020, which is hereby incorporated by reference in its entirety; and (ii) from U.S. Ser. No. 17/353,867, filed on Jun. 22, 2021, which is hereby incorporated by reference in its entirety.

The above-mentioned U.S. Ser. No. 18/129,865 is also a Continuation-in-Part (CIP) of U.S. Ser. No. 17/353,867, filed on Jun. 22, 2021, which is hereby incorporated by reference in its entirety.

This patent application is also a Continuation-in-Part (CIP) of U.S. Ser. No. 17/353,867, filed on Jun. 22, 2021, which is hereby incorporated by reference in its entirety.

The above-mentioned U.S. Ser. No. 17/353,867 is a Continuation-in-Part (CIP) of U.S. Ser. No. 16/362,665, filed on Mar. 24, 2019, now patent number U.S. Pat. No. 11,081,606 (issued on Aug. 3, 2021), which is hereby incorporated by reference in its entirety; which claims priority and benefit from U.S. 62/785,282, filed on Dec. 27, 2018, which is hereby incorporated by reference in its entirety.

The above-mentioned U.S. Ser. No. 17/353,867 is also a Continuation-in-Part (CIP) of PCT international application number PCT/IL2019/051416, having an international filing date of Dec. 26, 2019, which is hereby incorporated by reference in its entirety.

The above-mentioned PCT/IL2019/051416 claims priority and benefit: (i) from U.S. Ser. No. 16/362,665, filed on Mar. 24, 2019, now patent number U.S. Pat. No. 11,081,606 (issued on Aug. 3, 2021), which is hereby incorporated by reference in its entirety, and (ii) from U.S. 62/785,282, filed on Dec. 27, 2018, which is hereby incorporated by reference in its entirety.

The above-mentioned U.S. Ser. No. 18/129,865 is also a Continuation-in-Part (CIP) of U.S. Ser. No. 17/802,335, filed on Aug. 25, 2022, which is hereby incorporated by reference in its entirety; which is a National Stage of PCT international application number PCT/IL2021/050217, having an international filing date of Feb. 25, 2021, which is hereby incorporated by reference in its entirety; which claims priority and benefit from U.S. 62/982,536, filed on Feb. 27, 2020, which is hereby incorporated by reference in its entirety.

This patent application is also a Continuation-in-Part (CIP) of, and claims benefit and/or priority from: patent application U.S. Ser. No. 18/372,720, filed on Sep. 26, 2023, which is hereby incorporated by reference in its entirety.

The above-mentioned U.S. Ser. No. 18/372,720 is a Continuation of PCT international application number PCT/IL2022/050339, having an international filing date of Mar. 29, 2022, which is hereby incorporated by reference in its entirety.

The above-mentioned PCT/IL2022/050339 claims priority and benefit from U.S. 63/167,660, filed on Mar. 30, 2021, which is hereby incorporated by reference in its entirety.

The above-mentioned PCT/IL2022/050339 also claims priority and benefit from PCT international application number PCT/IL2021/051202, having an international filing date of Oct. 8, 2021, which is hereby incorporated by reference in its entirety.

The above-mentioned PCT/IL2022/050339 also claims priority and benefit from PCT international application number PCT/IL2021/051269, having an international filing date of Oct. 27, 2021, which is hereby incorporated by reference in its entirety.

The above-mentioned PCT/IL2022/050339 also claims priority and benefit from PCT international application number PCT/IL2022/050030, having an international filing date of Jan. 10, 2022, which is hereby incorporated by reference in its entirety.

The above-mentioned PCT/IL2022/050339 also claims priority and benefit from patent application U.S. Ser. No. 17/353,867, filed on Jun. 22, 2021, which is hereby incorporated by reference in its entirety.

The above-mentioned U.S. Ser. No. 18/372,720 is also a Continuation-in-Part (CIP) of U.S. Ser. No. 18/136,359, filed on Apr. 19, 2023, which is hereby incorporated by reference in its entirety. The above-mentioned U.S. Ser. No. 18/136,359 is a Continuation of PCT international application number PCT/IL2021/051269, having an international filing date of Oct. 27, 2021, which is hereby incorporated by reference in its entirety. The above-mentioned PCT/IL2021/051269 claims priority and benefit: (i) from U.S. 63/106,666, filed on Oct. 28, 2020, which is hereby incorporated by reference in its entirety; and also, (ii) from U.S. Ser. No. 17/353,867, filed on Jun. 22, 2021, which is hereby incorporated by reference in its entirety.

The above-mentioned U.S. Ser. No. 18/372,720 is also a Continuation-in-Part (CIP) of U.S. Ser. No. 18/217,620, filed on Jul. 3, 2023, which is hereby incorporated by reference in its entirety; which is a Continuation of the above-mentioned PCT international application number PCT/IL2022/050030, having an international filing date of Jan. 10, 2022, which is hereby incorporated by reference in its entirety.

This patent application is also a Continuation-in-Part (CIP) of U.S. Ser. No. 18/442,127, filed on Feb. 15, 2024, which is hereby incorporated by reference in its entirety.

The above-mentioned US 18/442,127 is a Continuation of PCT international application number PCT/IL2022/050899, having an international filing date of Aug. 18, 2022, which is hereby incorporated by reference in its entirety.

The above-mentioned PCT/IL2022/050899 claims priority and benefit: from U.S. 63/234,727, filed on Aug. 19, 2021, which is hereby incorporated by reference in its entirety; and from U.S. 63/238,808, filed on Aug. 31, 2021, which is hereby incorporated by reference in its entirety; and from U.S. 63/239,969, filed on Sep. 2, 2021, which is hereby incorporated by reference in its entirety.

### FIELD

Some embodiments relate to the field of solar panels and photovoltaic (PV) devices.

### BACKGROUND

The photovoltaic (PV) effect is the creation of voltage and electric current in a material upon exposure to light. It is a physical and chemical phenomenon.

The PV effect has been used in order to generate electricity from sunlight. For example, PV solar panels absorb sunlight or light energy or photons, and generate electricity through the PV effect.

### SUMMARY

Some embodiments provide improved or enhanced solar panels, solar cells, PV cells and/or PV devices, as well as methods and systems for producing them. The solar cells or PV devices may be flexible and/or rollable and/or foldable.

For example, a flexible solar module has an integral and internal thin metal foil, which is an integral layer of the solar cell stack. The thin metal foil collects and transports photovoltaic (PV) generated electric power from a plurality of regions of the solar module. A single metal foil can mechanically connect, and can collect PV-generated electric power, from multiple such solar cells; and is further coated from beneath by lamination or encapsulation layers.

For example, a plurality of solar modules are mounted on top of a support structure or a polymeric support substrate, that has metal wires running integrally therein. The metal wires are arranged in accordance with a pre-defined layout, such that most of the length of each metal wire is concealed and is protected within the support structure or the polymeric support substrate. An ending of each metal wire protrudes from the support structure or the polymeric support substrate, at a particular location that is configured to match an intended location of an electrical terminal of a PV module that is intended to be mounted on top of the support structure or the polymeric support substrate.

Furthermore, a plurality of solar modules are mounted on top of a polymeric support substrate or a polymeric support structure, that has metal wires running integrally therein; the metal wires are arranged in accordance with a pre-defined wiring layout, such that most of the length of each metal wire is concealed and is protected within the polymeric support substrate. An ending of each concealed metal wire protrudes outwardly from the polymeric support substrate at a particular location that is configured to match an intended location of an electrical terminal of a PV module that is intended to be mounted on the polymeric support substrate.

Some embodiments may provide other and/or additional benefits and/or advantages.

### BRIEF DESCRIPTION OF THE DRAWINGS

FIG. 1A is a schematic illustration of a joined solar module, in accordance with some demonstrative embodiments.

FIG. 1B is a schematic illustration of a cross-sectional view of a joined solar module having a metal back-sheet, in accordance with some demonstrative embodiments.

FIG. 1C is a cross-sectional view of a joined solar cell, in accordance with some demonstrative embodiments; demonstrating optional busbar(s) connected to the thin metal foil.

FIG. 1D is a cross-sectional view of a joined solar cell, in accordance with some demonstrative embodiments; demonstrating a semiconductor wafer (or a set of wafers) that is segmented or singulated or dashed, to provide or improve flexibility and/or mechanical resilience.

FIG. 1E is a cross-sectional view of a joined solar cell, in accordance with some demonstrative embodiments; demonstrating a semiconductor wafer that is segmented or grooved or trenched with downwardly-penetrating non-transcending grooves or craters.

FIG. 1F is a cross-sectional view of a joined solar cell, in accordance with some demonstrative embodiments; demonstrating a semiconductor wafer that is segmented or grooved or trenched with upwardly-penetrating non-transcending grooves or craters.

FIG. 1G is a cross-sectional view of a joined solar cell, in accordance with some demonstrative embodiments; demonstrating a semiconductor wafer that is segmented or grooved or trenched with alternating downwardly-penetrating and upwardly-penetrating non-transcending grooves or craters.

FIG. 1H is a cross-sectional view of a joined solar cell, in accordance with some demonstrative embodiments; demonstrating two solar cells or two solar sub-modules having a unified metal foil.

FIG. 2 is a photograph of a joined solar module that is adhered to an aluminum back-sheet, in accordance with some demonstrative embodiments.

FIG. 3 is a schematic illustration of a prior art photovoltaic device, comprised of four solar cells.

FIG. 4A is a schematic illustration of a first stage in the production of a polymeric support substrate for solar modules, in accordance with some demonstrative embodiments.

FIG. 4B is a schematic illustration of a second stage in the production of the polymeric support substrate having the additional metal wiring layout, in accordance with some demonstrative embodiments.

FIG. 4C is a schematic illustration of a third stage in the production of the polymeric support substrate for solar modules, in accordance with some demonstrative embodiments.

FIG. 4D is a schematic illustration of a PV device, which may be formed of the polymeric support substrate having mounted thereon a plurality of discrete solar cells/panels/modules, in accordance with some demonstrative embodiments.

FIG. 4E is a side-view of a polymeric support substrate with a plurality of solar modules mounted thereon, in accordance with some demonstrative embodiments.

### DETAILED DESCRIPTION OF SOME DEMONSTRATIVE EMBODIMENTS

The Applicants have realized that conventional solar panels are typically rigid, heavy, cumbersome, brittle and/or fragile units, that are typically installed on roofs or in other locations (e.g., a solar energy park, a solar energy farm, a solar power plant).

The Applicants have realized that there is a need to improve and/or enhance the structure and/or configuration and/or production process of solar panels and other PV devices, and particularly of flexible solar panels and other flexible PV devices; in order to improve or enhance their efficiency, durability, mechanical resilience or durability, thermal resilience or durability, physical resilience or durability, mechanical strength, modularity, and other characteristics; and/or in order to allow a more versatile utilization of such solar panels and other PV devices.

### Description of Some Embodiments Related to Metal Back-Sheet:

Some embodiments provide a solar module or a PV module, comprised of a plurality of solar cells or PV cells that are inter-connected to each other mechanically and electrically; arranged as an array or matrix or as a batch or an elongated string or other particular layout or structure. A polymeric laminate, or a polymeric lamination encapsulant or encapsulation component or lamination component, laminates and encapsulates the plurality of inter-connected solar cells to thus create a unified, singular, solar module. A metal back-sheet is electrically connected to the plurality of solar cells. In some embodiments, a single, unified, metal back-sheet serves the entirety of the solar module; and may be integrally stacked within the stack of the solar module.

In some embodiments, each solar cell may be an autonomously flexible solar cell, that does not break and does not brittle when flexed or curved or bent, and that is resilient to mechanical forces, and that can autonomously absorb and/or dissipate and/or withstand mechanical forces and mechanical shocks; for example, by being segmented or grooved or trenched with non-transcending gaps or “blind gaps” or craters or grooves or trenches, that penetrate some—but not all—of the thickness (or the depth) of a silicon layer or a semiconductor body or a semiconductor wafer; and optionally by having filler material(s) in such grooves or trenches or non-transcending gaps or non-transcending craters, to further absorb and/or dissipate mechanical forces and shocks.

In some embodiments, the entirety of the solar module is an autonomously flexible solar module, that does not break and does not brittle when flexed or curved or bent, and that is resilient to mechanical forces, and that can autonomously absorb and/or dissipate and/or withstand mechanical forces and mechanical shocks; for example, since at least some (or most, or all) of the discrete solar cells of the solar module are pre-segmented or grooved or trenched with non-transcending gaps or “blind gaps” or craters or grooves or trenches, that penetrate some—but not all—of the thickness (or the depth) of a silicon layer or a semiconductor body or a semiconductor wafer; and optionally by having filler material(s) in such grooves or trenches or non-transcending gaps or non-transcending craters, to further absorb and/or dissipate mechanical forces and shocks.

The Applicants have realized that a solar module or a solar panel may be produced as an assembly or arrangement or framework of multiple inter-connected solar cells (e.g., formed of a single semiconductor wafer, or formed of a plurality of inter-connected semiconductor wafers). The solar cells may be mechanically attached or joined to each other in order to form an array or matrix of solar cells, and to generate and aggregate a substantial amount of electricity from sunlight or other light. Each solar cell utilizes the PV effect to autonomously generate a small amount of electricity, that is collected or aggregated through metal wiring that aggregates electric voltage and/or electric current. The Applicants have realized that it may be beneficial to more effectively collect or aggregated the generated electricity from the plurality of solar cells, such that the electricity output of the solar module would increase, or such that the efficiency of the solar module would increase, or to avoid loss of electric energy that can be produced and collected but was not efficiently produced and/or collected.

The Applicants have realized that solar cells, as well as solar modules or solar sub-modules that include a plurality of solar cells, may be connected to each other in series or in parallel to generate and aggregate the electric power in accordance with a particular voltage/current rating or plan. The Applicants have further realized that a large solar module, which may include hundreds or even thousands of discrete solar cells, may aggregate a significant amount of electric power which may (in some situations) be dangerous, due to excessively high electric voltage or due to excessively high electric current, which in turn may cause a fire hazard or an over-heating hazard and/or which may result in electric power loss.

The Applicants have realized that in order to safely run a strong electric current while maintaining the electric voltage at a safe level, a large cross-section conductor may be needed; for example, a wide low-profile metal foil may be used for such purpose. The Applicants have also realized that if solar modules are produced individually and are then combined to a larger module, electrical connection between such current-carrying metal foils should be used, while also maintaining electrical isolation from the environment. Some embodiments of the present invention thus provide and utilize a metal foil, such as a thin aluminum foil or a thin copper foil (or, a thin foil of an alloy that includes aluminum and/or copper), as a replacement for metal cables or metal wires that were used in conventional solar modules, in order to aggregate and transfer the electric charges that are generated by the PV effect.

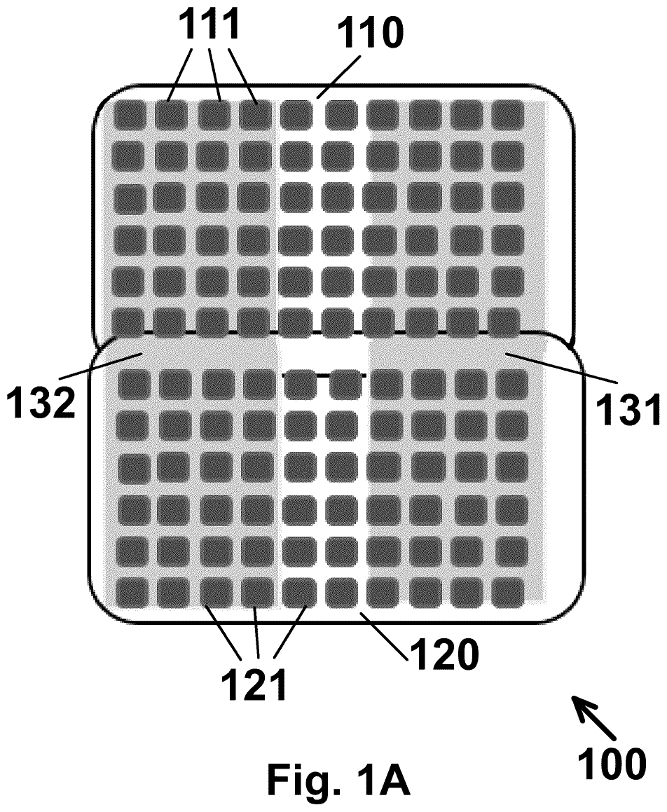

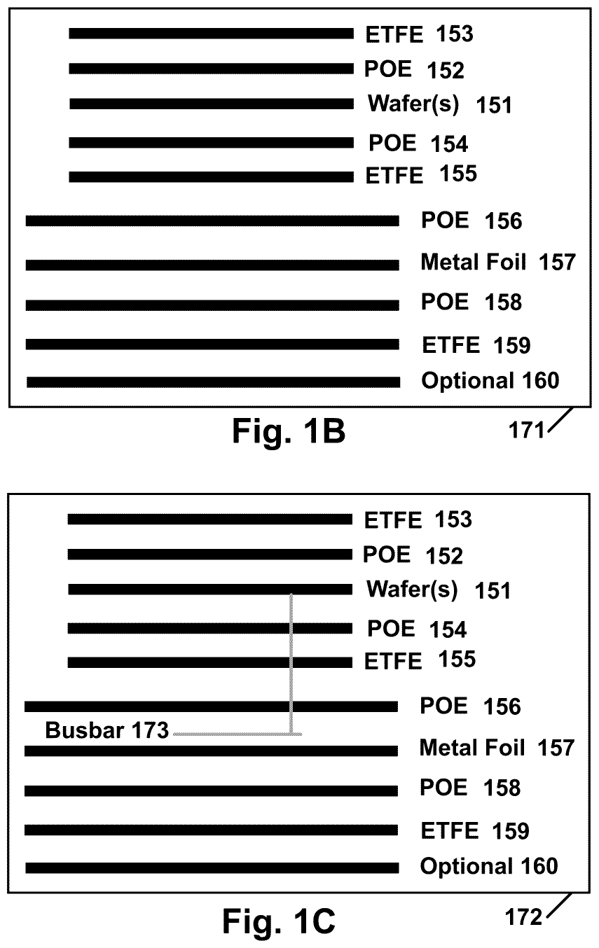

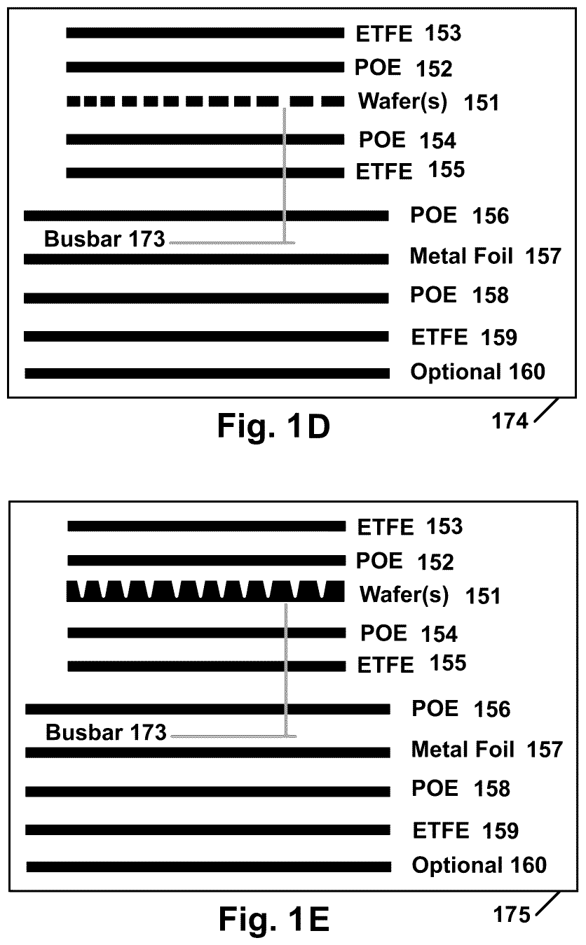

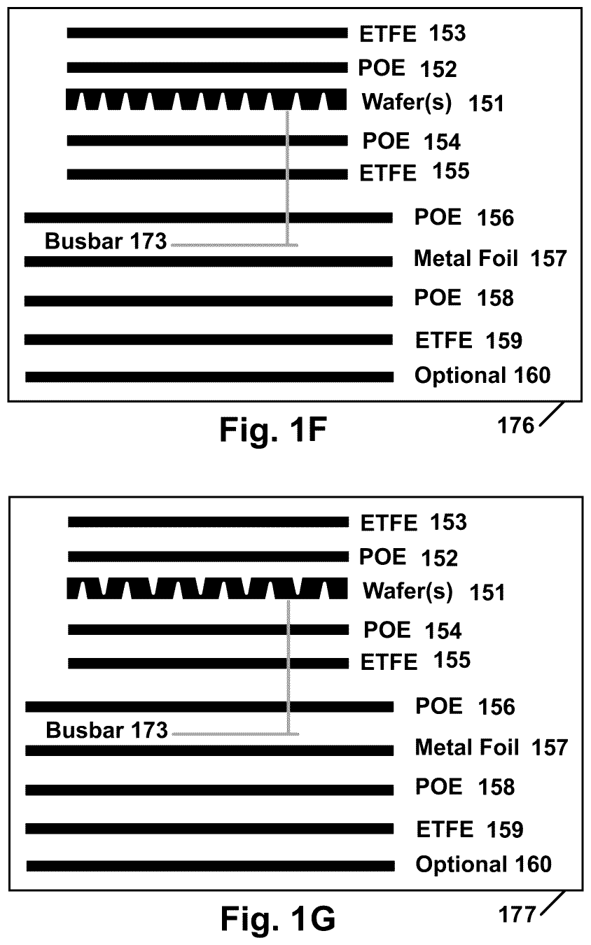

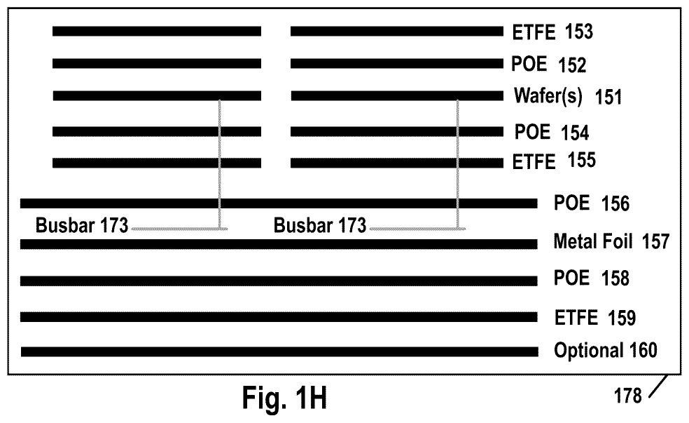

Reference is made to FIG. 1A, which is a schematic illustration of a joined solar module 100, in accordance with some demonstrative embodiments. Two or more solar sub-modules are produced; for example, solar sub-module 110 and solar sub-module 120; each one of the sub-module includes dozens or hundreds or even thousands of small-size solar cells (111, 121).

Sub-module 120 is placed near sub-module 110, or adjacent to it, or touching it, or such that the two sub-modules 110 and 120 slightly overlap. One or more metal foil strips are placed and connected (e.g., welded); for example, demonstrated by metal foil strip 131 and metal foil strip 132. Other number of metal foil strips may be used; and they may cover all the surface of the sub-modules (110 and 120). In some embodiments, a single, large, metal foil strip may suffice to provide full coverage; or several such metal foil strips may be used, optionally touching each other or being welded next to each other, or partially overlapping each other.

In accordance with some embodiments, the same metal foil strip (such as strip 131) is used across two (or more) adjacent or partially-overlapping solar sub-modules (such as 110 and 120), thus connecting those solar sub-modules both mechanically and electrically. In some embodiments, optionally, their mechanical connection may be achieved or strengthened by other means, for example, by gluing or bonding them, or stitching or stapling them to each other, or other mechanical connection methods.

Reference is made to FIG. 1B, which is a schematic illustration of a cross-sectional view of a joined solar module 171 having a metal back-sheet, in accordance with some demonstrative embodiments. The joined solar module includes semiconductor wafer(s) or solar cells that are arranged in a stack, and optionally, at least some of them are provided with (or are connected to) a busbar (e.g., to increase electric voltage); although some embodiments may be used in conjunction with busbar-free or busbar-less solar modules.

The semiconductor wafers are encapsulated and laminated with an encapsulant or encapsulation component or lamination component or lamination-and-encapsulation component; which may include one or more materials or layers or coatings, for example, polyolefin elastomer (POE), thermoplastic polyolefin (TPO), Ethylene-vinyl acetate (EVA) or poly (ethylene-vinyl acetate) (PEVA), thermoplastic polyurethane (TPU), silicone or poly-siloxane or a polymer made of siloxane, epoxy or epoxy resin(s) or poly-epoxides, or other suitable encapsulant(s).

In some embodiments, the encapsulant(s) are formed to encapsulate therein both sides or both surfaces of the semiconductor wafer. In some embodiments, optionally, the top-side or “sunny side” of the semiconductor wafer is coated or encapsulated or laminated with a first laminating encapsulant; whereas the bottom-side or “dark side” of the semiconductor wafer is coated or encapsulated or laminated with a second, different, laminating encapsulant. In some embodiments, optionally, the top-side or “sunny side” of the semiconductor wafer is coated or encapsulated or laminated with a first set of two or more laminating encapsulants; whereas the bottom-side or “dark side” of the semiconductor wafer is coated or encapsulated or laminated with a second, different, set of two or more laminating encapsulants. In some embodiments, optionally, one or more of the lamination/encapsulation layers may be formed of transparent or translucent material(s), which may allow at least partial passage of light therethrough.

In some embodiments, the joined solar module includes one or more front-sheet layer(s) and/or one or more back-sheet layers; for example, formed of Tedlar Polyester Tedlar (TPT), Polyvinyl butyral (PVB), Polyvinyl fluoride (PVF), Polyethylene terephthalate (PET), fluoro-polymer such as Polyvinylidene fluoride (PVDF), Ethylene tetrafluoroethylene (ETFE) or fluorine-based plastic, or a combination thereof.

In some embodiments, optionally, the encapsulant may be or may include a non-laminated encapsulant, or may be applied using an application process that is lamination free; for example, by spraying or spreading a coating or a paste, by spraying or dripping or brushing a solution, by dipping into a solution, by utilizing an adhesive layer or gluing or bonding layer(s), or the like.

In accordance with some embodiments, beneath the encapsulation layers, at or beneath the rear side of the solar module, a thin metal foil is attached or glued or bonded or welded or stitched or otherwise connected. The thin metal foil operates as a continuous electrical contact or as a continuous electrical conductor layer, that collects the PV-generated electricity from the plurality of solar cells that comprises the solar module. The thin metal foil may be or may include, for example, a thin aluminum foil, a thin copper foil, a thin foil of copper metallized aluminum, a thin foil of an alloy that includes aluminum, a thin foil of an alloy that includes copper, a thin foil of another metal, a thin foil of an alloy of other metals, or a combination of two or more of such materials; such as aluminium foil with a thin copper layer, or aluminum foil with a thin copper layer beneath it, or aluminum foil with a thin copper layer above it, or a thin copper layer sandwiched between two thin aluminum foils. In some embodiments, optionally, the thin metal foil may comprise two or more layers or two or more thin metal foils; such as, two or more layers of aluminum and/or copper, or two or more thin metal foils of aluminum and/or copper.

In some embodiments, optionally, one or more additional laminated polymers or lamination polymers or coating layers or encapsulation layers may be adhered or bonded or glued beneath the thin metal foil, or may be subject to a lamination process there or to other bonding or gluing or connection method there.

In the demonstrative implementation of FIG. 1B, joined solar cell 171 includes the following layers: a set of one or more semiconductor wafer(s) 151; the set being coated or encapsulated at its top side (towards the “sunny side”) with POE 152 and then with ETFE 153; the set also being coated or encapsulated at its bottom side (towards the “dark side”) with POE 154 and then with ETFE 155. Then, beneath those five layers, instead of running there discrete metal wires or discrete metal cables for collecting the PV-generated electric power, a thin metal foil 157 is placed, either directly touching the ETFE layer 155, or (in some implementations) touching an additional POE layer 156 that is added between the ETFE layer 155 and the thin metal foil 157. Beneath the thin metal foil 157 that collects the PV-generated electric power, there are: an additional POE layer 158, then an additional ETFE layer 159; and optionally, one or more protective layers or lamination layers or encapsulation layers, shown as Optional layer(s) 160.

In a demonstrative embodiment, joined solar cell 171 is busbar free, and does not include any busbar. Reference is also made to FIG. 1C, which is a cross-sectional view of a joined solar cell 172, in accordance with some demonstrative embodiments; in which busbar(s) 173 are connected (e.g., from the thin metal foil 157 or its vicinity, to the semiconductor wafer(s) 151 or their vicinity) while, in some embodiments, penetrating one or more layers of the overall structure.

Reference is made to FIG. 1D, which is a cross-sectional view of a joined solar cell 174, in accordance with some demonstrative embodiments; in which the semiconductor wafer 151 (or the set of wafers) is segmented or singulated or dashed, to provide or increase or improve flexibility and/or mechanical resilience of the solar cell.

Reference is made to FIG. 1E, which is a cross-sectional view of a joined solar cell 175, in accordance with some demonstrative embodiments; in which the semiconductor wafer 151 (or the set of wafers) is segmented or grooved or trenched with non-transcending grooves or with non-transcending gaps or “blind gaps” or craters, to provide or increase or improve flexibility and/or mechanical resilience of the solar cell. The trenches or grooves are penetrating downwardly, from the “sunny side” towards the “dark side” of the solar cell, through (for example) between 75 to 99 percent of the depth (or thickness) of the semiconductor wafer.

Reference is made to FIG. 1F, which is a cross-sectional view of a joined solar cell 176, in accordance with some demonstrative embodiments; in which the semiconductor wafer 151 (or the set of wafers) is segmented or grooved or trenched with non-transcending grooves or with non-transcending gaps or “blind gaps” or craters, to provide or increase or improve flexibility and/or mechanical resilience of the solar cell. The trenches or grooves are penetrating upwardly, from the “dark side” towards the “sunny side” of the solar cell, through (for example) between 75 to 99 percent of the depth (or thickness) of the semiconductor wafer.

Reference is made to FIG. 1G, which is a cross-sectional view of a joined solar cell 177, in accordance with some demonstrative embodiments; in which the semiconductor wafer 151 (or the set of wafers) is segmented or grooved or trenched with non-transcending grooves or with non-transcending gaps or “blind gaps” or craters, to provide or increase or improve flexibility and/or mechanical resilience of the solar cell. The trenches or grooves are penetrating in a zigzag pattern or an alternating structure; for example, first upwardly (from the “dark side” towards the “sunny side” of the solar cell), then downwardly, then upwardly again, and so forth; through (for example) between 75 to 99 percent of the depth (or thickness) of the semiconductor wafer. The embodiment demonstrated in FIG. 1G is a non-limiting example of segmentation from different sides of the solar cell; alternating sides may be segmented according to a specific sequence pattern, or in a random or scattered manner.

Reference is made to FIG. 1H, which is a cross-sectional view of a joined solar cell 178, in accordance with some demonstrative embodiments; demonstrating two solar cells or two solar sub-modules, each one of them having its own five layers 151-155; optionally having a small vertical gap between the two solar cells or solar sub-modules; which are then connected (mechanically and electrically) to a single, unified, common, thin metal foil 157, with the additional coating/encapsulation/lamination/protection layers that surround it or that are beneath it. More than two such discrete solar cells of solar sub-modules may be connected similarly; for example, dozens or even hundreds may be connected onto a single, unified, thin metal foil.

For demonstrative purposes, some of the drawings may show busbar(s) that may optimally be used, or which may assist in electric power collection and/or aggregation and/or transport; and which may be connected (mechanically and electrically) to the thin metal foil. However, some embodiments may include a busbar-free solar cell, which does not include any busbars; as the thin metal foil may perform, by itself, the electric power collection and/or aggregation and/or transport.

It is noted that in accordance with some embodiments, the thin metal foil is stacked with the solar modules as demonstrated in FIGS. 1B to 1H, and is an integral and internal component of the joined solar module, and operates as an integral and incorporated part of the stack of solar modules and polymers. The thin metal foil is not an external add-on, that solar cells or solar modules are glued onto, such as, merely in order to arrange solar cells on a thin foil that can be flexible; but rather, the thin metal foil in accordance with some embodiments is an internal and integral component of the joined solar module, which serves multiple functionalities internally within the joined solar module: to electrically connect a plurality of discrete solar cells, to electrically connect a plurality of discrete solar sub-modules or modules, to mechanically connect a plurality of solar sub-modules or modules, to collect and aggregate the PV-generated electric power without causing an unsafe level of current and/or voltage and while preventing over-heating (hazards or problems which may be caused if metal wires or metal cables are used, instead of the innovative utilization of a thin metal foil). In accordance with the various embodiments demonstrated above and/or herein, the thin metal foil may be used as the only current conductor or as the exclusive current conductor; or may be used in combination with other current conductors such as busbars, interconnectors (“dogbones”), discrete wires, parallel wires, a mesh of electrical wires, and/or cables.

In some embodiments, optionally, the thin metal foil may also be electrically connected to the stack of the joined solar module through busbars. Such configuration may be an alternative, in some embodiments, to structuring the thin metal foil as an internal and integral component of the stack of the joined solar module; and in this alternative, the thin metal foil is connected via busbars to the stack of the joined solar module. Other suitable methods may be used to connect, mechanically and/or electrically, the thin metal foil or a thin metal sheet to the solar sub-modules and/or to the joined solar module.

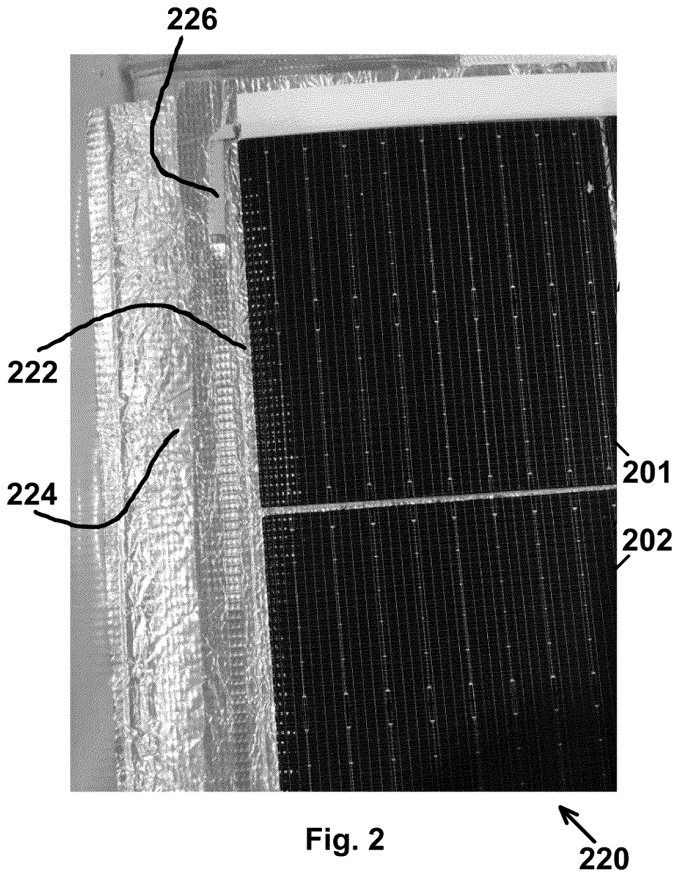

Reference is made to FIG. 2, which is a photograph of a joined solar module 200 that is adhered to an aluminum back-sheet, in accordance with some demonstrative embodiments. For example, a first flexible solar module 201 and a second flexible solar module 202 are shown, positioned side by side and having a thin gap between them; and they are laminated together by a common set of polymers 222 which connects them mechanically and holds them together and thus creates the flexible, joined, solar module 200.

In some embodiments, for example, a solar cell or solar module is electrically connected by internal metal wires, and has a metal foil to provide external connection or to provide connection to a second, co-located, solar cell or solar module. For example, connector 226 is connected to the internal wiring of solar module 201, and to metal foil 224 on its other side. The metal foil 224 is then the electrical connection to another solar module.

In other embodiments, beneath the rear surface or the back surface of each of solar modules 201 and 202, the encapsulated solar cells are adhered to a thin metal foil 224. Instead of electrically connecting each solar module (201, 202) so as to collect from it the PV-generated electric energy, a single electrical connector 226 is attached to the thin metal foil 224 for this purpose, and collects all the PV-generated electric energy of the entirety of the joined solar module 200.

In accordance with some embodiments, the utilization of the thin metal foil enhances and improves the electrical connectivity of the solar modules and their plurality of solar cells; and forms a joined solar module that is more effective and more efficient (in PV-generated electric production) compared to conventional, separate, solar panels. Moreover, the thin metal foil may further operate as a physical or mechanical barrier, that keeps the joined solar module and its components free of moisture, wetness, humidity, liquids, dust, sand, or other contaminants or debris or objects from the environment in which the joined solar module is placed.

It is noted that some embodiments of the present invention may be implemented in conjunction with, or within, various suitable types of solar cells or solar panels; for example, crystalline (c-Si) solar cells, monocrystalline (mono-Si) solar cells, polycrystalline (multi-Si) solar cells, amorphous silicon (a-Si) solar cells, wafer-based solar cells, semiconductor-based solar cells, thin-film solar cells (TFSC), Cadmium telluride (CdTe) solar cells, Copper indium gallium selenide (CI(G)S) solar cells, Perovskite solar cells, and/or other types of solar cells.

In some embodiments, a single, unified, common, thin metal foil, may be utilized to mechanically and electrically connect two neighboring (or adjacent, or bordering) solar cells or solar sub-modules, which may be of two, different, solar cell types; or which may implement two, different, solar cell technologies; or which may implement two, different, PV-based electricity generation techniques; or which may have two, different, thickness values of physical depth or physical thickness values; or which may have two, different, flexibility levels or rigidity levels.

### Description of Some Embodiments Related to a Support Substrate Having Internal Embedded Wiring:

In the discussion herein, the term “support substrate” refers to a polymeric surface or a polymeric article or a polymeric body a polymeric structure or a polymeric object, that is generally flat or planar, and that may optionally be flexible and/or may have flexing capability or bending capability, and that may optionally be foldable and/or rollable; and which may be suitable for mechanically or physically carrying thereon, or supporting on top of it, or holding thereon, or having mounted thereon, one or more solar cells or solar modules or solar panels, or a plurality of co-located or neighboring or adjacent solar cells or solar modules or solar panels.

It is further clarified that the “support substrate” or the “polymeric support substrate” that are discussed herein, and/or their polymeric layers (e.g., the base layer and the upper layer), are external to the solar cell/panel/module, and are not an internal part of a solar cell/panel/module, and are not to be confused with a “semiconductor substrate” that some solar cells may include therein. The “support substrate” or the “polymeric support substrate” that are discussed herein, are not (and do not include) any semiconductor material and/or any semiconductor wafer and/or any semiconductor layer and/or any silicon.

Some embodiments provide embedded or integral wiring within a support structure, or a support substrate, or a polymeric support structure, that is intended for supporting thereon (or for mounting thereon) a plurality of solar cells or solar panels or solar modules; and particularly, metal wiring that are integrally embedded, and at least partially concealed or hidden or protected, within a support structure or a support substrate or a polymeric support substrate that would then support solar cells or modules or panels that are mounted on it or that are attached or glued or bonded on its top surface.

For demonstrative purposes, some portions of the discussions herein may relate to a polymeric and/of foamed and/or flexible support substrate or support structure. However, these are non-limiting examples; and some other embodiments may include or may utilize non-polymeric support substrates, and/or non-flexible or non-foamed support substrates.

The Applicants have realized that PV-generated electricity is typically conveyed or transported from a solar cell to a target device (or to a target location) through metal wires and leads. The Applicants have realized that solar cells or PV devices may have, or may be connected to, a vast amount of lead wires and/or metal cables and/or junction boxes.

The Applicants have realized that conventional structures of wires and cables for transporting PV-generated electric power from a solar module may be cumbersome, or may have many wires or cables dangling or shifting from side to side or being partially loose along a surface or near a surface; or having wires or cables that may be prone to disconnection or ripping or tearing due to mechanical forces or mechanical shocks (e.g., during transportation of the PV device, or during installation, or during placement in storage or removal out of storage); or may expose such wires and cables to weather hazards or physical hazards or other environmental hazards that may damage the entirety of cables or at least segments thereof.

The Applicants have realized that it may be beneficial to structure, configure and/or arrange wiring in an efficient or improved layout, such as in an organized cable layout or cable-like layout, and particularly in a layout that protects and/or conceals large segments of the required wiring. Accordingly, some embodiments provide an innovative wiring layout for transporting PV-generated electric power, from a plurality of co-located or adjacent or neighboring solar modules or solar panels, to a target device or an electricity storage device (e.g., battery or power cell) or to a target electricity-consuming device; wherein the wirings are integrally embedded and/or internally embedded as an integral and internal part of (and are at least partially concealed and/or hidden and/or protected and or “buried” within) a polymeric support component or a polymeric support substrate or a polymeric support structure that is intended to support or carry thereon solar cells or panels or modules.

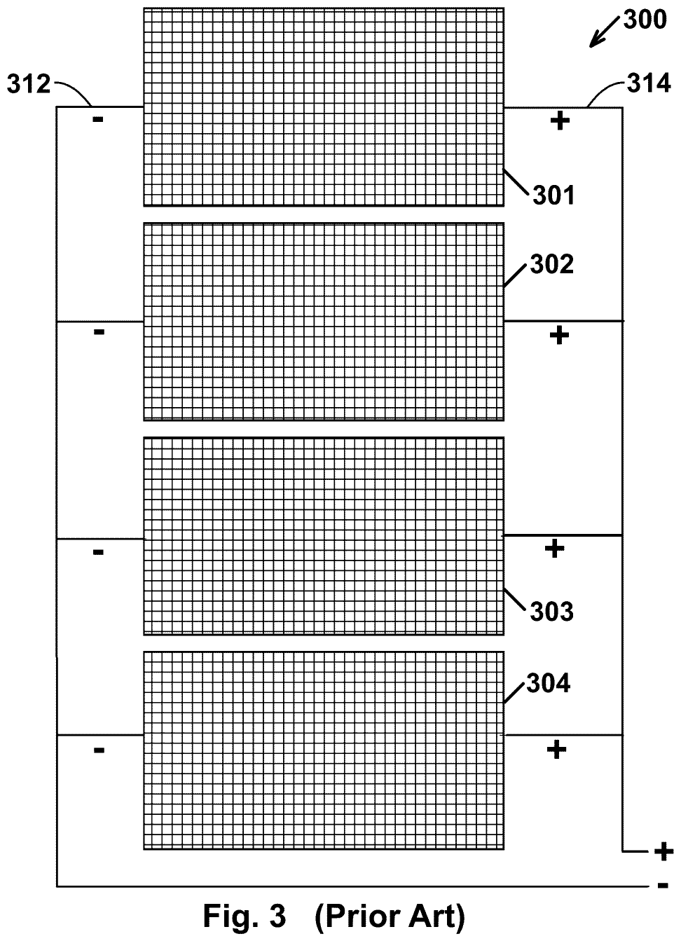

Reference is made to FIG. 3, which is a schematic illustration of a prior art PV device 300, comprised of four solar cells 301-304. Each of solar cells 301-304 has its own negative terminal 312 and has its own positive terminal 314. Terminals of two or more solar cells may be wired or electrically connected in parallel or in series. However, realized the Applicants, in any case, there are typically wires that are connected to each of the solar cells 301-304 and/or between or among two or more of the solar cells 301-304. In some prior art systems, realized the Applicants, solar panels may be individually connected in parallel; such that negative (minus) cables and positive (plus) cables may be connected to the solar panels on the same side of the panels or on different/opposites sides of the panels. Other connection structures are known, typically requiring complex or cumbersome external wirings; and such wiring may be exposed to environmental hazards, or may dangle or shift their location, or may become loose, or may be ripped or torn due to mechanical shocks or mechanical forces (e.g., particularly during transportation and/or deployment of a PV device).

The Applicants have realized that some solar cells or solar panels, particularly if they are configured to be flexible and/or rollable and/or foldable, are often mounted on top of a support substrate which carries them and/or provides mechanical support and/or physical support. The support substrate may be formed of a hard or rigid material, or semi-hard/semi-rigid material, or a flexible material, or a combination of two or more such materials, depending on the particular implementation goals. The Applicants have realized that such support substrate may be produced and prepared in advance, prior to the mounting of solar panels thereon, to included wiring that are embedded (and are at least partially concealed and protected) integrally therein; such that the support substrate is readily configured to receive upon it the solar cells/panels/modules that correspond the embedded wiring within the support substrate, and such that the mounted solar cells/panels/modules can be easily and efficiently connected, mechanically and electrically, to small, protruding, segments or ends of such generally-concealed or generally-protected internal wirings of the support substrate.

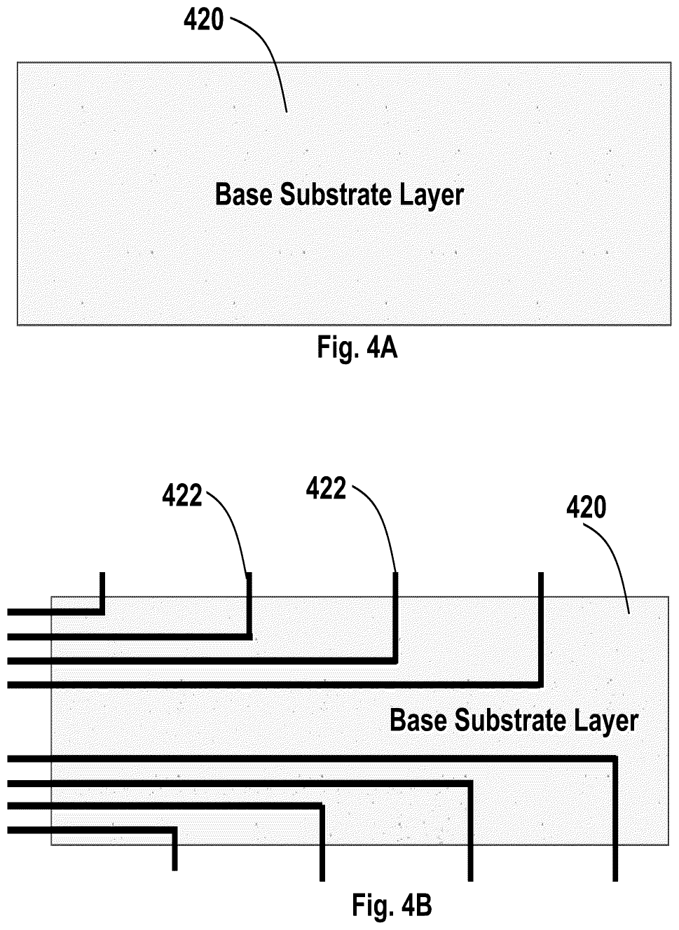

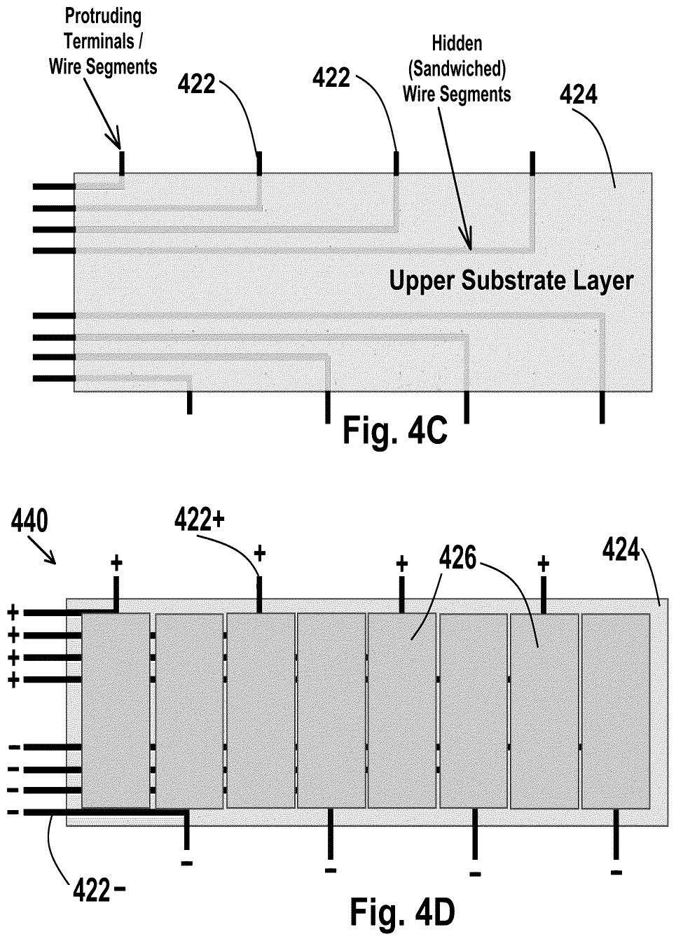

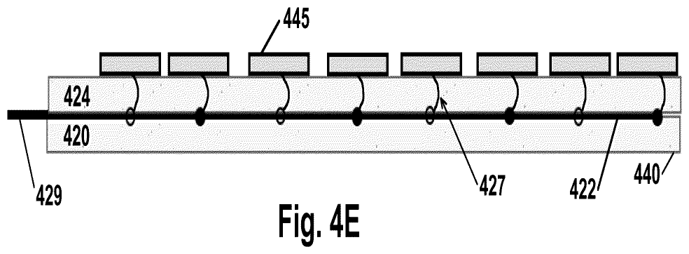

Reference is made to FIG. 4A, which is a schematic illustration of a first stage in the production of a polymeric support substrate for solar modules, in accordance with some demonstrative embodiments. For example, a polymeric support substrate base layer 420 is cut according to the required dimensions for a specific application or purpose. The polymeric support substrate layer 420 is formed, for example, of one or more polymeric material(s); for example, polyurethane, polyethylene, polypropylene, or a combination of two or more such materials.

Reference is made to FIG. 4B, which is a schematic illustration of a second stage in the production of the polymeric support substrate having the additional metal wiring layout, in accordance with some demonstrative embodiments. For example, metal wiring 422 is placed on the polymeric support substrate base layer 420 in accordance with a pre-defined pattern or layout or arrangement, which corresponds to the intended locations of the solar modules (or solar panels, or solar cells) that will be mounted on that particular polymeric support substrate; wherein each solar module that is intended to be mounted on the polymeric support substrate has at least two (or, in some implementations, has exactly two) main electrical terminals. It is noted that any reference to metal wiring (e.g., wiring 422) may also refer to other conducting elements, such as, busbars and/or thin metal foils.

Reference is made to FIG. 4C, which is a schematic illustration of a third stage in the production of the polymeric support substrate for solar modules, in accordance with some demonstrative embodiments. An upper (or top side) polymeric support substrate layer 424 is placed on top of the polymeric support substrate base layer 420 and on top of the wiring 422 (which are mostly concealed now, and are shown with a lighter shade of black for demonstrative purposes only); such that wiring 422 is embedded or sandwiched or trapped or concealed or hidden or protected between the two polymeric support substrate layers (420 and 424); wherein each wire of the wiring 422 has a terminal (at each ending of the wire) or a small segment (at each ending of the wire) that protrudes outwardly from the two “sandwiching” or enclosing layers of the combined, dual-layer, polymeric support substrate.

In some embodiments, the polymeric support substrate base layer 420 and the polymeric support substrate upper layer 424 are formed of the same material, or from the same set of two or more materials. In other embodiments, the polymeric support substrate base layer 420 and the polymeric support substrate upper layer 424 are formed of two different polymeric materials, or from two different sets of polymeric materials; for example, in order to provide different properties to each layer of the dual-layer polymeric support substrate, or such that the entirety of the dual-layer polymeric support substrate will have different properties from the properties of each substrate layer by itself.

In some embodiments, the polymeric support substrate base layer 420 and the polymeric support substrate upper layer 424 have the same thickness of depth. In other embodiments, the polymeric support substrate base layer 420 and the polymeric support substrate upper layer 424 have different values of thickness of depth; for example, in order to provide different properties to each layer of the dual-layer polymeric support substrate, or such that the entirety of the dual-layer polymeric support substrate will have different properties from the properties of each substrate layer by itself.

In some embodiments, the polymeric support substrate base layer 420 and the polymeric support substrate upper layer 424 are formed of the same material, or from the same set of two or more materials, and have the same, generally uniform, level of flexibility or rigidity or stiffness or bending capability or flexing capability. In other embodiments, the polymeric support substrate base layer 420 and the polymeric support substrate upper layer 424 are formed of two different polymeric materials, or from two different sets of polymeric materials; for example, in order to provide different properties of flexibility or rigidity or stiffness or banding capability or flexing capability to each layer of the dual-layer polymeric support substrate; or such that the entirety of the dual-layer polymeric support substrate will have different flexibility or rigidity or stiffness or bending capability or flexing capability properties from the corresponding properties of each substrate layer by itself.

In some embodiments, the polymeric support substrate base layer 420 and the polymeric support substrate upper layer 424 are formed of the same material, or from the same set of two or more materials, and have the same, generally uniform, density or mass or weight. In other embodiments, the polymeric support substrate base layer 420 and the polymeric support substrate upper layer 424 are formed of two different polymeric materials, or from two different sets of polymeric materials; for example, in order to provide different properties of density or mass or weight to each layer of the dual-layer polymeric support substrate; or such that the entirety of the dual-layer polymeric support substrate will have different properties of density or mass or weight relative to the corresponding properties of each substrate layer by itself.

Similarly, in some embodiments, only one support substrate layer, or both layers of the dual-layer polymeric support substrate, may be formed of a foamed polymer or may comprise a foaming agent or foaming material(s) or foamed region(s) or foamed components or sponge-based or sponge-like components; or may be hollow or partially hollow; or may include foamed regions or foamed material or bubbled materials or bubbled regions or may include polymer-trapped air bubbles or polymer-trapped air pockets; or may be solid or dense or and fully filled and non-hollow; or may be stiff and/or rigid; or the like.

In accordance with some embodiments, the polymeric support substrate base layer 420 and the polymeric support substrate upper layer 424, with the wiring 422 sandwiched or trapped or encapsulated or protected between them, may be adhered, glued, bonded, pressed while heated, cured, or may be subject to two or more of such operations; for example, to produce a unified or singular polymeric support substrate body, whose layers cannot be detached or separated (at all, or under regular operational forces). Other suitable methods may be used for embedding or inserting wiring into the support substrate; or for producing a support substrate that encapsulates or traps or conceals therein such wiring or a particular wiring layout. For example, in some implementations, metal wires having particular shapes and curvatures may be inserted, one by one or as a batch of wires, manually or via a wire placing machine or a wire insertion machine, through a polymeric substrate or a foamed substrate or a sponge or other generally-soft or flexible polymeric material or foamed polymeric material; and optionally by applying angular force(s) on the edge of an inserted wire in order to rotate it as it traverses within the polymeric substrate. In other embodiments, a polymeric support substrate may be formed by utilizing a template or a cavity or a mold, such as via injection molding of hot or molten polymers or plastic materials, while leaving cavities or tunnels in the resulting article that can accommodate wires traversing therein. Other suitable methods may be used.

In accordance with some embodiments, one end of each wire 424 protrudes outwardly relative to the surface area of the two substrate layers (420 and 424). The other end of each wire 424 is configured to be electrically (and mechanically) connected to the solar cells/modules/panels. Such connection may be implemented, for example, by passing generally-short metal cables or metal wires through the polymeric support substrate upper layer 424, or by having the wires exit from the sandwich of substrate layers 420 and 424 and then loop upwardly to meet the relevant electrical terminal(s) of the solar panel (whose electrical output wires may similarly be looped, downwardly), or by other suitable connection means.

In some embodiments, each solar cell/panel/module that is mounted on the dual-layer polymeric support substrate, may be connected at least to: (I) a tip (or an ending) of a first wire 424 that is the Positive wire, wherein the first wire traverses internally and integrally through the polymeric support substrate and then protrudes outwardly through another region of the polymeric support substrate upper layer 424; and also, (II) a tip (or an ending) of a second wire 424 that is the Negative wire, wherein the second wire traverses internally and integrally through the polymeric support substrate and then protrudes outwardly through another region of the polymeric support substrate upper layer 424; such that two distinct and separate wires, each one of them being internal and integral to the polymeric support substrate, transport the PV-generated electric power from such solar cell/panel/module.

Reference is made to FIG. 4D, which is a schematic illustration of a PV device 440, which may be formed of the polymeric support substrate having mounted thereon a plurality of discrete solar cells/panels/modules, in accordance with some demonstrative embodiments. For example, a plurality of solar modules 426 (or solar cells, or solar panels) can be adhered or bonded or glued to the side of the polymeric support substrate upper layer 424; using heat (e.g., flame adhering), curing, gluing, bonding, using an adhesive material or an adhesive layer or a double-sided adhesive layer, or using mechanical connection mechanism(s) (e.g., male-female connectors; hook and eye connectors; pins and holes connectors); using a stitching connection, using staples, using soldering or soldered connections, using tape, or using a combination of two or more connection mechanisms. The number, size, shape, and type of the solar modules 426 may be in accordance with the requirements of goals of a particular implementation.

Each of the solar modules 426 is pre-configured or pre-structured to have its wiring (or, its electrical output terminals) to be located and/or structured in order to match at least one region of the polymeric support substrate, and particularly in order to match at least a portion of the pattern or layout of the wiring arrangement that was laid in between the polymeric support substrate base layer 420 and the polymeric support substrate upper layer 424. Each solar module 426 has at least two electrical terminals that are configured to be electrically connected to one of at least two, corresponding, wires of the wiring 422; for example, demonstrated as positive terminal 422+ and as negative terminal 422−.

Reference is made to FIG. 4E, which is a side-view of a polymeric support substrate 440 with a plurality of solar modules 445 mounted thereon, in accordance with some demonstrative embodiments. The electrical wiring 422 is sandwiched between, and is protected and mostly concealed by, the two layers (420 and 424) of the polymeric support substrate. A portion or a segment 429 of the electrical wiring 422 protrudes out of the polymeric support substrate 440, transporting outwardly the PV-generated electric power. Each of the solar modules 445 is connected, at two sides or at two connection points, to the wiring 422; for example, via looped connections 427 or via other type of connection(s). Solar modules 445 are shown spaced-apart and are not drawn to scale, in order to clearly demonstrate their discrete nature; although in some embodiments, the plurality of solar modules 445 may touch each other, or may have a smaller or narrower gap among them, or may slightly overlap each other.

In some embodiments, one layer or both layers of the polymeric support substrate may be formed of a polymeric material, which may be flexible or non-rigid or non-stiff, or which may provide at least some level of flexibility or elasticity or flexing capability or bending capability to the entire substrate support body; and thus may be appropriate for mounting thereon one or more already-flexible solar modules or panels or cells; such that the entirety of the resulting PV device or PV article has flexibility or bending capabilities.

Furthermore, such PV device or PV article may be assembled and then transported to a target location, with the solar modules already being mounted and remaining mounted on the polymeric support substrate; without the need to unmount or to remove the solar modules from the top of the polymeric support substrate; and/or while maintaining the solar modules connected to and mounted on the top surface of the polymeric support substrate even while the PV device is bent or flexed or folded or rolled; and while concealing and protecting most of the length of the wirings as they are internal and integral to the polymeric support substrate and are thus protected from mechanical shocks and environmental hazards; thereby reducing costs and volume as well as safety and efficiency of transportation of the PV device, or of storage of the PV device while in transit or while it is waiting to be deployed.

Additionally, the integral and internal wiring (or at least a substantial segment of the wiring) is protected within the polymeric support substrate, during transport and/or storage of the PV device, or in case the PV device and its solar modules are configured to be floated on a body of water or a water reservoir, or when the PV device is transported to an intended location for deployment there, or while the PV device is actually deployed and operational at such location. In such implementations, the polymeric support substrate layer(s) may be or may include foam(s) or foamed polymers that also have buoyancy characteristics. In some embodiments, the Specific Weight of the polymeric support substrate, including its two layers and including its internal wiring, is smaller than 1; such that the polymeric support substrate can float on water. In some embodiments, the Specific Weight of the entirety of the PV device or PV article, including the polymeric support substrate (with its two layers and with its internal wiring) and the solar modules mounted thereon, is smaller than 1; such that the entirety of the PV device can float on water. In some embodiments, optionally, a tube of wiring or wire-endings or wire-segments may emerge from each of the solar modules and/or from an edge of the polymeric support substrate, to protect the wiring that may be electrically connected to an inverter that can be positioned on shore or on the bank of the water reservoir or on a nearby floating unit.

In other embodiments, the polymeric support substrate layers (420 and/or 424) may be formed of rigid or stiff materials, that provide to the overall PV device robustness or mechanical toughness or mechanical resilience, for applications in which such properties are required.

In some embodiments, the wiring 422 that is embedded within the polymeric support substrate is pre-provided as flat or generally-flat lines or strips of metal (rather than as tubular metal segments), to facilitate the curing or adhering of the sandwiched polymeric support substrate.

Additional Features, Which May be Combined With Any of the Above-Mentioned Features, and/or That May Implement Any of the Above-Mentioned Features:

Optionally, some embodiments may be utilized in conjunction with PV devices and/or solar panels and/or components and/or methods that are described in patent number U.S. Pat. No. 11,081,606, titled “flexible and rollable photovoltaic cell having enhanced properties of mechanical impact absorption”, which is hereby incorporated by reference in its entirety; and/or in conjunction with components, structures, devices, methods, systems and/or techniques that are described in patent application number U.S. Ser. No. 17/353,867, filed on Jun. 22, 2021, published as US 2021/0313478, which is hereby incorporated by reference in its entirety; and/or with solar panels or solar cells or PV devices that are singulated or segmented, or that are flexible and/or rollable and/or foldable, and/or that include “blind gaps” or non-transcending gaps or craters. Some embodiments may provide a flexible and rollable PV cell or solar cell; wherein a silicon body or semiconductor body or semiconductor substrate or semiconductor wafer has non-transcending craters or “blind gaps” that penetrate into between 80 percent and 99 percent of a total thickness of the semiconductor body (or wafer, or substrate), and that do not penetrate into an entirety of the total thickness of the semiconductor body (or wafer, or substrate); wherein said non-transcending craters or “blind gaps” increase flexibility/or and mechanical resilience and/or mechanical shock absorption of the PV cell. In some embodiments, some, or most, or all of the non-transcending craters or “blind gaps” contain a filler material having mechanical force absorption properties, which provides mechanical shock absorption properties and/or mechanical force dissipation properties to the PV cell.

In some embodiments, each of the solar cells is rollable and flexible by itself; and is a single PV device or is a single PV article, that is comprised of a single semiconductor substrate or a single semiconductor wafer or a single semiconductor body; which is monolithic, e.g., is currently, and has been, a single item or a single article or a single component that was formed as (and remained) a single component; such that each solar cell is not formed as a collection or two or more separate units or as a collection of two or more entirely-separated or entirely-discrete or entirely-gapped units that were arranged or placed together in proximity to each other yet onto a metal foil or onto a metal film or onto a flexible or elastic foil or film.

In some embodiments, each single solar cell that is flexible and rollable by itself, is not a collection and is not an arrangement and is not an assembly of multiple discrete solar cells of PV modules, that each one of them has its own discrete and fully separated semiconductor substrate and/or its own discrete and fully separated semiconductor wafer and/or its own discrete and fully separated semiconductor body, and that have been merely placed to assembled or arranged together (or mounted together, or connected together) onto or beneath a flexible foil or a flexible film; but rather, the each single solar cell has a single unified semiconductor substrate or semiconductor body or semiconductor wafer that is common to, and is shared by, all the sub-regions or areas or portions of that single solar cell which includes therein (in that unified single semiconductor substrate or wafer or body) those non-transcending craters or non-transcending gaps or “blind gaps” that penetrate only from one side (and not from both sides), which do not reach all the way through and do not reach all the way to the other side of the unified single semiconductor substrate or wafer or body.

In some embodiments, each solar cell may be, or may include, a mono-crystalline PV cell or solar panel or solar cell, a poly-crystalline PV cell or solar panel or solar cell, a flexible PV cell or solar cell that is an Interdigitated Back Contact (IBC) solar cell having said semiconductor wafer with said set of non-transcending gaps, and/or other suitable type of PV cell or solar cell.

Some portions of the discussion above and/or herein may relate to regions or segments or areas, of the semiconductor body or substrate or wafer (or PV cell, or PV device); yet those “segments” are still touching each other and/or inherently connected to each other and/or non-separated from each other, as those “segments” are still connected by at least a thin portion or a thin bottom-side surface of the semiconductor substrate (or wafer, or body), which still holds and includes at least 1 (or at least 2, or at least 3, or at least 5, or at least 10, or at least 15, or at least 20, or at least 25, or at least 33; but not more than 50, or not more than 40) percent of the entire depth or the entire thickness (or the maximum thickness or depth) of the semiconductor substrate or body or wafer; as those “segments” are still connected at their base through such thin layer, and those “segments” have between them (or among them) the non-transcending gaps or the “blind gaps” or the non-transcending craters that thus separate those “segments” but that do not fully divide or fully break or fully isolate any two such neighboring “segments” from each other. Upon its production, and prior to attaching the solar cells onto the floating medium layer, each such flexible and rollable solar cell is freestanding and carrier-less and non-supported.

In some embodiments, the non-transcending gaps or the “blind gaps” or craters or slits or grooves, are introduced and are formed only at a first side or at a first surface of the semiconductor substrate or body or wafer, and are not formed at both of the opposite surfaces (or sides) thereof.

In some embodiments, the non-transcending gaps or the “blind gaps” or craters or slits or grooves, are introduced and are formed only at a first side or at a first surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; and they are not formed at the other (e.g., opposite, non-active) side or surface (e.g., the side that is not intended to be facing the sunlight or the light, or the side that is not intended to be producing electricity based on the PV effect).

In other embodiments, the non-transcending gaps or the “blind gaps” or craters or slits or grooves, are not introduced and are not formed at the side or surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; but rather, those non-transcending gaps or the “blind gaps” or craters or slits or grooves are formed at the other (e.g., opposite, non-active) side or surface, which is the side that is not intended to be facing the sunlight or the light, or the side that is not intended to be producing electricity based on the PV effect. Some implementations with this structure may advantageously provide the mechanical shock absorption and the mechanical forces dissipation capability, yet may also provide or maintain or achieve an increased level of PV-based electricity production since the gaps do not reduce the area of the light-exposed side or the light-facing side of the PV device.

In still other embodiments, the non-transcending gaps or the “blind gaps” or craters or slits or grooves, are introduced and are formed at both sides or at both surfaces of the semiconductor substrate or body or wafer; yet with an offset among the gaps of the first side and the gaps of the second side, in a zig-zag pattern of those gaps which zig-zag across the two sides of the semiconductor wafer or substrate or body; for example, a first gap located at the top surface on the left; then, a second gap located at the bottom surface to the right side of the first gap and not overlapping at all with the first gap; then, a third gap located at the top surface to the right side of the second gap and not overlapping at all with the second gap; then, a fourth gap located at the bottom surface to the right side of the third gap and not overlapping at all with the third gap; and so forth. In such structure, for example, any single point or any single location or any single region of the remaining semiconductor wafer or substrate or wafer, may have a gap or a crater or a “blind gap” only on one of its two sides, but not on both of its sides.

In yet other embodiments, the non-transcending gaps or the “blind gaps” or craters or slits or grooves, are introduced and are formed at both sides or at both surfaces of the semiconductor substrate or body or wafer; not necessarily with an offset among the gaps of the first side and the gaps of the second side, and not necessarily in a zig-zag pattern; but rather, by implementing any other suitable structure or pattern that still provides the mechanical shock resilience, and while also maintaining a sufficiently-thin layer of semiconductor substrate or body or wafer that is not removed and that is resilient to mechanical shocks and mechanical forces due to the craters or gaps that surround it.

Some embodiments may include and/or may utilize one or more units, devices, connectors, wires, electrodes, and/or methods which are described in United States patent application publication number US 2016/0308155 A1, which is hereby incorporated by reference in its entirety. For example, some embodiments may include and may utilize an electrode arrangement which is configured to define or create a plurality of electricity collection regions, such that within each of the collection regions, at least two sets of conducting wires are provided such that they are insulated from each other, and the at least two sets of conducting wires are connected either in parallel or in series between the collection regions to thus provide accumulating voltage of charge collection. Some embodiments may include an electric circuit for reading-out or collection or aggregation of the generated electricity, configured as an electrodes arrangement, including conducting wires arranged in the form of nets covering zones of a pre-determined area. The electrodes arrangement may be configured or structured to be stretched (e.g., rolled out) along the surface of the PV cell, and may be formed by at least two sets of conducting wires, and may cover a plurality of collection zones or collection regions.

Within each of the electricity collection zones or electricity aggregation zones, the different conducting wires are insulated from each other, to provide a certain voltage between them. At a transition between zones, the negative charges collecting conductive wire of one zone, is electrically connected to the positive charges collecting conductive wire of the adjacent or the consecutive zone. Thus, within each of the collection zones, the different sets of conducting wires are insulated from each other, while being connected in series between the zones. This configuration of the electrode arrangement allows accumulation or aggregation of electric voltage generated by charge collection along the surface of the PV device. The configuration of the electrode arrangement provides a robust electric collection structure.

The internal connections between the sets of conducting wires allow energy collection even if the surface being covered is not continuous, e.g., if a perforation occurs in the structure of the net. This feature of the electrode arrangement allows for using this technique on any surface exposed to photon radiation, while also allowing discontinuity if needed and without limiting or disrupting the electric charge collection.

In some embodiments, a set of conducting wires may be embedded in or within a flexible and/or adhesive and/or transparent-to-light plastic foil or plastic film or encapsulant, is embedded immediately beneath such film or foil or encapsulant, or immediately over such film or foil or encapsulant, or is included within such film or foil or encapsulant (e.g., such that the plastic or encapsulant is to the right and to the left of each conducting wire but does not obstruct and does not prevent the conducting wire from touching the solar cell surface for collecting electric charge therefrom). In some embodiments, the sunny-side surface and/or the dark-side surface of each solar cell, or the top-side and/or the bottom-side of each solar cell, may be coated with an adhesive or a transparent adhesive and/or with an electrically-conducting adhesive and/or an electrically-conducting transparent adhesive, to enable gluing or bonding of such surface of the PV cell to the set of conducting wires, for long-term bonding or at least for short-term bonding during the production process before the plastic foil is heated and/or before the PV cell is laminated or encapsulated.

In some embodiments, some, or all, or a majority of, the non-transcending craters or “blind gaps”, are filled with one or more filler material(s), which further provide mechanical shock absorption and/or mechanical shock dissipation and/or thermal resilience and/or mechanical resilience and/or physical resilience and/or chemical resilience and/or mechanical durability and/or thermal durability and/or physical durability and/or chemical durability.

In some embodiments, each of the solar cells in the array, and/or the entirety of the array of solar cells, is laminated and/or encapsulated, within a single lamination layer or a single encapsulation layer, or within two or more layers or coatings or encapsulants, which may be transparent and enable light to pass there-through, or which may be translucent and may enable at least 75% of light to pass there-through, and which may provide further mechanical resilience and damage protection to the solar cells and their array.

In some embodiments, a device comprises a self-floating, rollable, flexible, photovoltaic article, that is formed of a plurality of flexible and rollable and mechanically-resilient solar cells that are inter-connected as a generally planar (yet flexible and rollable) array. Each of said flexible and rollable and mechanically-resilient solar cells has (I) a sunny-side or top-side surface that is configured to absorb light, and (II) a back-side or bottom-side surface that is opposite to said sunny-side surface and is not necessarily configured to absorb light (e.g., in some implementations it does not absorb light and it is a “dark side”; or, in other implementations, it also absorbs light and it is a “sunny side”). Each of said flexible and rollable and mechanically-resilient solar cells is configured to generate electric current from light via the photovoltaic effect.

Some embodiments provide a flexible Photovoltaic (PV) cell, comprising: (a) a semiconductor wafer, having a top surface that is intended to face a light source, and having a bottom surface that is opposite to said top surface; wherein the top surface of the semiconductor wafer is covered by at least one encapsulation layer or lamination layer; wherein the bottom surface of the semiconductor wafer is covered by at least one encapsulation layer or lamination layer; and also, (b) a metal foil, connected beneath the at least one encapsulation layer or lamination layer that cover from beneath said bottom surface of the semiconductor wafer; wherein the metal foil is an internal and integral layer of the semiconductor wafer, and is an internal and integral part of a solar cell stack of said PV cell; wherein the metal foil collects and transports PV-generated electric power from a plurality of regions of the PV cell; and also, (c) one or more encapsulation layers or lamination layers, connected beneath said metal foil, to provide mechanical protection to said metal foil and said PV cell.

In some embodiments, the PV cell excludes, and does not include, any metal cables or metal wires that collect PV-generated electric power from a vicinity of said semiconductor wafer; and wherein only said metal foil collects and transports PV-generated electric power from the vicinity of said semiconductor wafer.

In some embodiments, the PV cell excludes, and does not include, any metal busbars that collect PV-generated electric power from a vicinity of said semiconductor wafer; and wherein only said metal foil collects and transports PV-generated electric power from the vicinity of said semiconductor wafer.

In some embodiments, the PV cell comprises at least one busbar that collects some, but not all, of the PV-generated electric power from a vicinity of said semiconductor wafer; and wherein said metal foil collects and transports some, but not all of the PV-generated electric power from the vicinity of said semiconductor wafer.

In some embodiments, the PV cell comprises busbars that collect all of the PV-generated electric power from a vicinity of said semiconductor wafer; wherein said metal foil collects and transports all of the PV-generated electric power, that was collected by said busbars, to an external recipient unit or to a co-located PV cell.

In some embodiments, the metal foil is a thin metal foil selected from the group consisting of: a thin aluminum foil, a thin copper foil, a thin foil formed of an alloy comprising aluminum, a thin foil formed of an alloy comprising copper; a thin foil formed of an alloy comprising aluminum and copper; a thin foil formed of two or more layers of aluminum and/or copper.

In some embodiments, the metal foil is connected within said flexible PV cell using a welding-based connection.

In some embodiments, the metal foil is a single, unified, metal foil that is connected to both: a first solar sub-module that comprises a first group of miniature PV cells that are formed of a first segment of the semiconductor wafer, and a second, neighboring, solar sub-module that comprises a second group of miniature PV cells that are formed of a second segment of the semiconductor wafer; wherein said single, unified, metal foil collects and transports PV-generated electric power from both the first solar sub-module and the second, neighboring, solar sub-module.

In some embodiments, each of the solar sub-modules excludes, and does not include, any metal cables or metal wires that collect PV-generated electric power from a vicinity of said semiconductor wafer; and wherein only said metal foil collects and transports PV-generated electric power from the vicinity of said semiconductor wafer and from the first and the second solar sub-modules.

In some embodiments, the semiconductor wafer has non-transcending craters that penetrate into between 80 percent and 99 percent (or, between 75 and 99 percent; or, between 66 and 99 percent; or, between 50 and 99 percent) of a total thickness of the semiconductor wafer, and that do not penetrate into an entirety of the total thickness of the semiconductor wafer; wherein said non-transcending craters in the semiconductor wafer increase flexibility and mechanical resilience and mechanical shock absorption of said PV cell. In some embodiments, at least some of (or, most of; or, all of) said non-transcending craters contain a filler material having mechanical force absorption properties, which provides mechanical shock absorption properties to said PV cell.

Some embodiments provide a flexible Photovoltaic (PV) article, comprising: a plurality of discrete, neighboring, PV modules; wherein each PV module comprises one or more flexible PV cells; wherein the plurality of discrete, neighboring, PV modules are mounted on a top surface of a support structure; wherein metal wires are embedded internally and integrally within the support structure, and transport PV-generated electric power from said PV modules towards a target unit; wherein most of the total length of all the metal wires, is integrally concealed and internally protected within the support structure; wherein two short ending segments of each metal wire, protrude out of the support structure; wherein one short ending segment of each pair of ending segments of each metal wire, protrudes from the support structure at a particular location that corresponds to an intended location of an electrical terminal of an PV module that is intended to be mounted on top of the support structure.

In some embodiments, at least 50 percent of a total length of each metal wire, is concealed and is mechanically protected within said support structure.

In some embodiments, each particular PV module, that is mounted on top of the support structure, has a negative terminal and a positive terminal; wherein the negative terminal of said particular PV module, is connected to a first non-concealed ending segment of a first metal wire; wherein the positive terminal of said particular PV module, is connected to a first non-concealed ending segment of a second, different, metal wire; wherein a second non-concealed ending segment of the first metal wire, and a second non-concealed ending segment of the second metal wire, protrude outwardly from the support substrate transport the PV-generated electric power from said particular PV module.

In some embodiments, each metal wire of said metal wires, that are internal and integral to the polymeric support substrate, has: (i) a proximal end segment that is configured to connect with an electrical terminal of a PV module, and (ii) a distal end segment that is configured to output PV-generated electric power from said PV module; wherein each PV module is configured to connect to two metal wires that transport the PV-generated electric power of said PV module; wherein the support structure has particular locations for each proximal end segment, that match the intended placement of a PV module on top of the support structure.

In some embodiments, the structure and locations of metal wires within the polymeric support substrate, and the locations at which the metal wires protrude out of the support structure, are configured to match the intended positioning of the PV modules on top of the support structure, and are configured to enable efficient and short-distance electrical connection between a terminal of each PV module and an ending of each metal wire of the support structure.

In some embodiments, the support structure is a polymeric support substrate.

In some embodiments, the support structure is a polymeric support substrate that is flexible and rollable.

In some embodiments, the support structure is a polymeric support substrate that comprises: a first polymeric support layer, that is generally planar; a second polymeric support layer, that is generally planar, and that is generally parallel to the first polymeric support layer; wherein the metal wires are integrally and non-removably sandwiched between the first polymeric support layer and the second polymeric support layer.

In some embodiments, the polymeric support substrate comprises a foamed polymeric material that makes the polymeric support substrate lightweight and/or flexible and/or buoyant on water.

In some embodiments, the polymeric support substrate comprises a polymeric base layer and a polymeric upper layer, that sandwich and conceal between them at least 50 percent of a length of each of the metal wires.

In some embodiments, the polymeric support substrate comprises a polymeric base layer and a polymeric upper layer, that sandwich and conceal between them at least 50 percent of a cumulative total length of all the metal wires.

In some embodiments, the polymeric base layer is formed of a first polymeric material having a first set of characteristics; wherein the polymeric upper layer is formed of a second, different, polymeric material having a second, different, set of characteristics.

In some embodiments, the polymeric support substrate, including the metal wires that are integrally embedded therein, is flexible and rollable; wherein an entirety of the PV article, including the polymeric support substrate and the PV modules that are mounted thereon, is flexible and rollable.

Some embodiments provide a method of producing a flexible Photovoltaic (PV) cell, the method comprising: (a) providing a semiconductor wafer, having a top surface that is intended to face a light source, and having a bottom surface that is opposite to said top surface; covering the top surface of the semiconductor wafer by at least one encapsulation layer or lamination layer; covering the bottom surface of the semiconductor wafer by at least one encapsulation layer or lamination layer; (b) connecting a metal foil, beneath the at least one encapsulation layer or lamination layer that cover from beneath said bottom surface of the semiconductor wafer; wherein the metal foil is produced as an internal and integral layer of the semiconductor wafer, and is an internal and integral part of a solar cell stack of said PV cell; wherein the metal foil collects and transports PV-generated electric power from a plurality of regions of the PV cell; (c) connecting one or more encapsulation layers or lamination layers, beneath said metal foil, to provide mechanical protection to said metal foil and said PV cell.

In some embodiments, step (b) of connecting the metal foil is performed instead of, and not in addition to, connecting any metal cables or metal wires for collection of PV-generated electric power from a vicinity of said semiconductor wafer; wherein only said metal foil collects and transports PV-generated electric power from the vicinity of said semiconductor wafer.

In some embodiments, step (b) of connecting the metal foil is performed instead of, and not in addition to, connecting or forming any metal busbars for collection of PV-generated electric power from a vicinity of said semiconductor wafer; wherein only said metal foil collects and transports PV-generated electric power from the vicinity of said semiconductor wafer.

In some embodiments, step (b) of connecting the metal foil is performed in addition to connecting or forming metal busbars for collection of PV-generated electric power from a vicinity of said semiconductor wafer; wherein only said metal busbars collect PV-generated electric power from the vicinity of said semiconductor wafer; and wherein only the metal foil transports the already-collected PV-generated electricity from the solar cell to an external recipient (or, connects that solar cell to another, co-located/neighboring, solar cell).

In some embodiments, the method comprises: providing a support structure, that has metal wires embedded integrally and internally therein; herein ending segments of the embedded metal wires protrude outwardly of the support structure at particular locations that are configured to match the locations of corresponding electrical terminals of PV modules that are intended to be mounted on top of said support structure.

In some embodiments, providing the support structure comprises: producing a polymeric support substrate, that has metal wires embedded integrally and internally therein; wherein ending segments of the embedded metal wires protrude outwardly of the polymeric support substrate at particular locations that are configured to match the locations of corresponding electrical terminals of PV modules that are intended to be mounted on top of said polymeric support substrate.

In some embodiments, producing the polymeric support substrate comprises: providing a polymeric base layer that is generally planar; placing a pre-defined wiring layout of metal wires on top of the polymeric base layer, wherein each metal wire is mostly on top of the polymeric base layer, wherein two short ending segments of each metal wire protrude out of the polymeric base layer; placing a polymeric upper layer that is generally planar, on top of the wiring layout and on top of the polymeric base layer; performing a heating and/or bonding process that integrally and non-removably embeds the wiring layout of metal wires as internally sandwiched component of the polymeric support substrate.

The terms “plurality” and “a plurality”, as used herein, include, for example, “multiple” or “two or more”. For example, “a plurality of items” includes two or more items.

References to “one embodiment”, “an embodiment”, “demonstrative embodiment”, “various embodiments”, “some embodiments”, and/or similar terms, may indicate that the embodiment(s) so described may optionally include a particular feature, structure, or characteristic, but not every embodiment necessarily includes the particular feature, structure, or characteristic. Furthermore, repeated use of the phrase “in one embodiment” does not necessarily refer to the same embodiment, although it may Similarly, repeated use of the phrase “in some embodiments” does not necessarily refer to the same set or group of embodiments, although it may

As used herein, and unless otherwise specified, the utilization of ordinal adjectives such as “first”, “second”, “third”, “fourth”, and so forth, to describe an item or an object, merely indicates that different instances of such like items or objects are being referred to; and does not intend to imply as if the items or objects so described must be in a particular given sequence, either temporally, spatially, in ranking, or in any other ordering manner.

Functions, operations, components and/or features described herein with reference to one or more embodiments, may be combined with, or may be utilized in combination with, one or more other functions, operations, components and/or features described herein with reference to one or more other embodiments. Some embodiments may thus comprise any possible or suitable combinations, re-arrangements, assembly, re-assembly, or other utilization of some or all of the modules or functions or components that are described herein, even if they are discussed in different locations or different chapters of the above discussion, or even if they are shown across different drawings or multiple drawings.

While certain features of some demonstrative embodiments have been illustrated and described herein, various modifications, substitutions, changes, and equivalents may occur to those skilled in the art. Accordingly, the claims are intended to cover all such modifications, substitutions, changes, and equivalents.

What is claimed is:

1. A flexible Photovoltaic (PV) cell, comprising:
(a) a semiconductor wafer, having a top surface that is intended to face a light source, and having a bottom surface that is opposite to said top surface;
wherein the top surface of the semiconductor wafer is covered by at least one encapsulation layer or lamination layer;
wherein the bottom surface of the semiconductor wafer is covered by at least one encapsulation layer or lamination layer;
(b) a metal foil, connected beneath the at least one encapsulation layer or lamination layer that cover from beneath said bottom surface of the semiconductor wafer;
wherein the metal foil is an internal and integral layer of the semiconductor wafer, and is an internal and integral part of a solar cell stack of said PV cell;
wherein the metal foil collects and transports PV-generated electric power from a plurality of regions of the PV cell;
(c) one or more encapsulation layers or lamination layers, connected beneath said metal foil, to provide mechanical protection to said metal foil and said PV cell.

2. The flexible PV cell according to claim 1,
wherein the PV cell excludes, and does not include, any metal cables or metal wires that collect PV-generated electric power from a vicinity of said semiconductor wafer; and wherein only said metal foil collects and transports PV-generated electric power from the vicinity of said semiconductor wafer.

3. The flexible PV cell according to claim 2,
wherein the PV cell excludes, and does not include, any metal busbars that collect PV-generated electric power from a vicinity of said semiconductor wafer; and wherein only said metal foil collects and transports PV-generated electric power from the vicinity of said semiconductor wafer.

4. The flexible PV cell according to claim 2,
wherein the PV cell comprises at least one busbar that collects some, but not all, of the PV-generated electric power from a vicinity of said semiconductor wafer; and wherein said metal foil collects and transports some, but not all of the PV-generated electric power from the vicinity of said semiconductor wafer.

5. The flexible PV cell according to claim 2,
wherein the PV cell comprises busbars that collect all of the PV-generated electric power from a vicinity of said semiconductor wafer;
wherein said metal foil collects and transports all of the PV-generated electric power, that was collected by said busbars, to an external recipient unit or to a co-located PV cell.

6. The flexible PV cell according to claim 2,
wherein the metal foil is a thin metal foil selected from the group consisting of:
a thin aluminum foil,
a thin copper foil,
a thin foil formed of an alloy comprising aluminum,
a thin foil formed of an alloy comprising copper;
a thin foil formed of an alloy comprising aluminum and copper;
a thin foil formed of two or more layers of aluminum and/or copper.

7. The flexible PV cell according to claim 2, wherein the metal foil is connected within said flexible PV cell using a welding-based connection.

8. The flexible PV cell according to claim 2,
wherein the metal foil is a single, unified, metal foil that is connected to both:
a first solar sub-module that comprises a first group of miniature PV cells that are formed of a first segment of the semiconductor wafer, and
a second, neighboring, solar sub-module that comprises a second group of miniature PV cells that are formed of a second segment of the semiconductor wafer;
wherein said single, unified, metal foil collects and transports PV-generated electric power from both the first solar sub-module and the second, neighboring, solar sub-module.

9. The flexible PV cell according to claim 8,
wherein each of the solar sub-modules excludes, and does not include, any metal cables or metal wires that collect PV-generated electric power from a vicinity of said semiconductor wafer;
and wherein only said metal foil collects and transports PV-generated electric power from the vicinity of said semiconductor wafer and from the first and the second solar sub-modules.

10. The flexible PV cell according to claim 2,
wherein the semiconductor wafer has non-transcending craters that penetrate into between 80 percent and 99 percent of a total thickness of the semiconductor wafer, and that do not penetrate into an entirety of the total thickness of the semiconductor wafer;
wherein said non-transcending craters in the semiconductor wafer increase flexibility and mechanical resilience and mechanical shock absorption of said PV cell.

11. The flexible PV cell according to claim 2,
wherein the semiconductor wafer has non-transcending craters that penetrate into between 80 percent and 99 percent of a total thickness of the semiconductor wafer, and that do not penetrate into an entirety of the total thickness of the semiconductor wafer;
wherein at least some of said non-transcending craters contain a filler material having mechanical force absorption properties, which provides mechanical shock absorption properties to said PV cell.

12. A flexible Photovoltaic (PV) article, comprising:
a plurality of discrete, neighboring, PV modules; wherein each PV module comprises one or more flexible PV cells according to claim 2;
wherein the plurality of discrete, neighboring, PV modules are mounted on a top surface of a support structure,
wherein metal wires are embedded internally and integrally within the support structure, and transport PV-generated electric power from said PV modules towards a target unit;
wherein most of the total length of all the metal wires, is integrally concealed and internally protected within the support structure;
wherein two short ending segments of each metal wire, protrude out of the support structure; wherein one short ending segment of each pair of ending segments of each metal wire, protrudes from the support structure at a particular location that corresponds to an intended location of an electrical terminal of an PV module that is intended to be mounted on top of the support structure.

13. The flexible PV article according to claim 12,
wherein at least 50 percent of a total length of each metal wire, is concealed and is mechanically protected within said support structure.

14. The flexible PV article according to claim 12,
wherein each particular PV module, that is mounted on top of the support structure, has a negative terminal and a positive terminal;
wherein the negative terminal of said particular PV module, is connected to a first non-concealed ending segment of a first metal wire;
wherein the positive terminal of said particular PV module, is connected to a first non-concealed ending segment of a second, different, metal wire;
wherein a second non-concealed ending segment of the first metal wire, and a second non-concealed ending segment of the second metal wire, protrude outwardly from the support substrate transport the PV-generated electric power from said particular PV module.

15. The flexible PV article according to claim 12,
wherein each metal wire of said metal wires, that are internal and integral to the polymeric support substrate, has: (i) a proximal end segment that is configured to connect with an electrical terminal of a PV module, and (ii) a distal end segment that is configured to output PV-generated electric power from said PV module;
wherein each PV module is configured to connect to two metal wires that transport the PV-generated electric power of said PV module;
wherein the support structure has particular locations for each proximal end segment, that match the intended placement of a PV module on top of the support structure.

16. The flexible PV article according to claim 12,
wherein the structure and locations of metal wires within the polymeric support substrate, and the locations at which the metal wires protrude out of the support structure,
are configured to match the intended positioning of the PV modules on top of the support structure,
and are configured to enable efficient and short-distance electrical connection between a terminal of each PV module and an ending of each metal wire of the support structure.

17. The flexible PV article according to claim 12,
wherein the support structure is a polymeric support substrate.

18. The flexible PV article according to claim 12,
wherein the support structure is a polymeric support substrate that is flexible and rollable.

19. The flexible PV article according to claim 12,
wherein the support structure is a polymeric support substrate that comprises:
a first polymeric support layer, that is generally planar;
a second polymeric support layer, that is generally planar, and that is generally parallel to the first polymeric support layer;
wherein the metal wires are integrally and non-removably sandwiched between the first polymeric support layer and the second polymeric support layer.

20. The flexible PV article according to claim 19,
wherein the polymeric support substrate comprises a foamed polymeric material that makes the polymeric support substrate lightweight and/or flexible and/or buoyant on water.

21. The flexible PV article according to claim 17,
wherein the polymeric support substrate comprises a polymeric base layer and a polymeric upper layer, that sandwich and conceal between them at least 50 percent of a length of each of the metal wires.

22. The flexible PV article according to claim 17,
wherein the polymeric support substrate comprises a polymeric base layer and a polymeric upper layer, that sandwich and conceal between them at least 50 percent of a cumulative total length of all the metal wires.

23. The flexible PV article according to claim 22,
wherein the polymeric base layer is formed of a first polymeric material having a first set of characteristics;
wherein the polymeric upper layer is formed of a second, different, polymeric material having a second, different, set of characteristics.

24. The flexible PV article according to claim 17,
wherein the polymeric support substrate, including the metal wires that are integrally embedded therein, is flexible and rollable;
wherein an entirety of the PV article, including the polymeric support substrate and the PV modules that are mounted thereon, is flexible and rollable.

25. A method of producing a flexible Photovoltaic (PV) cell, the method comprising:
(a) providing a semiconductor wafer, having a top surface that is intended to face a light source, and having a bottom surface that is opposite to said top surface;
covering the top surface of the semiconductor wafer by at least one encapsulation layer or lamination layer;
covering the bottom surface of the semiconductor wafer by at least one encapsulation layer or lamination layer;
(b) connecting a metal foil, beneath the at least one encapsulation layer or lamination layer that cover from beneath said bottom surface of the semiconductor wafer;
wherein the metal foil is produced as an internal and integral layer of the semiconductor wafer, and is an internal and integral part of a solar cell stack of said PV cell;
wherein the metal foil collects and transports PV-generated electric power from a plurality of regions of the PV cell;
(c) connecting one or more encapsulation layers or lamination layers, beneath said metal foil, to provide mechanical protection to said metal foil and said PV cell.

26. The method according to claim 25,
wherein step (b) of connecting the metal foil is performed instead of, and not in addition to, connecting any metal cables or metal wires for collection of PV-generated electric power from a vicinity of said semiconductor wafer;
wherein only said metal foil collects and transports PV-generated electric power from the vicinity of said semiconductor wafer.

27. The method according to claim 26,
wherein step (b) of connecting the metal foil is performed instead of, and not in addition to, connecting or forming any metal busbars for collection of PV-generated electric power from a vicinity of said semiconductor wafer;
wherein only said metal foil collects and transports PV-generated electric power from the vicinity of said semiconductor wafer.

28. The method according to claim 25, further comprising:
providing a support structure, that has metal wires embedded integrally and internally therein,
wherein ending segments of the embedded metal wires protrude outwardly of the support structure at particular locations that are configured to match the locations of corresponding electrical terminals of PV modules that are intended to be mounted on top of said support structure.

29. The method according to claim 28,
wherein providing the support structure comprises:
producing a polymeric support substrate, that has metal wires embedded integrally and internally therein,
wherein ending segments of the embedded metal wires protrude outwardly of the polymeric support substrate at particular locations that are configured to match the locations of corresponding electrical terminals of PV modules that are intended to be mounted on top of said polymeric support substrate.

30. The method according to claim 28,
wherein producing the polymeric support substrate comprises:
providing a polymeric base layer that is generally planar;
placing a pre-defined wiring layout of metal wires on top of the polymeric base layer, wherein each metal wire is mostly on top of the polymeric base layer, wherein two short ending segments of each metal wire protrude out of the polymeric base layer;
placing a polymeric upper layer that is generally planar, on top of the wiring layout and on top of the polymeric base layer;
performing a heating and/or bonding process that integrally and non-removably embeds the wiring layout of metal wires as internally sandwiched component of the polymeric support substrate.

31. A flexible Photovoltaic (PV) article, comprising:
a plurality of discrete, neighboring, PV modules; wherein each PV module comprises one or more flexible PV cells that is configured to convert light into electricity;
wherein the plurality of discrete, neighboring, PV modules are mounted on a top surface of a support structure,
wherein metal wires are embedded internally and integrally within the support structure, and transport PV-generated electric power from said PV modules towards a target unit;
wherein most of the total length of all the metal wires, is integrally concealed and internally protected within the support structure;
wherein two short ending segments of each metal wire, protrude out of the support structure; wherein one short ending segment of each pair of ending segments of each metal wire, protrudes from the support structure at a particular location that corresponds to an intended location of an electrical terminal of an PV module that is intended to be mounted on top of the support structure.

32. The flexible PV article according to claim 31,
wherein at least 50 percent of a total length of each metal wire, is concealed and is mechanically protected within said support structure.

33. The flexible PV article according to claim 32,
wherein each particular PV module, that is mounted on top of the support structure, has a negative terminal and a positive terminal;
wherein the negative terminal of said particular PV module, is connected to a first non-concealed ending segment of a first metal wire;
wherein the positive terminal of said particular PV module, is connected to a first non-concealed ending segment of a second, different, metal wire;
wherein a second non-concealed ending segment of the first metal wire, and a second non-concealed ending segment of the second metal wire, protrude outwardly from the support substrate transport the PV-generated electric power from said particular PV module.

34. The flexible PV article according to claim 32,
wherein each metal wire of said metal wires, that are internal and integral to the polymeric support substrate, has: (i) a proximal end segment that is configured to connect with an electrical terminal of a PV module, and (ii) a distal end segment that is configured to output PV-generated electric power from said PV module;
wherein each PV module is configured to connect to two metal wires that transport the PV-generated electric power of said PV module;
wherein the support structure has particular locations for each proximal end segment, that match the intended placement of a PV module on top of the support structure.

35. The flexible PV article according to claim 32,
wherein the structure and locations of metal wires within the polymeric support substrate, and the locations at which the metal wires protrude out of the support structure,
are configured to match the intended positioning of the PV modules on top of the support structure,
and are configured to enable efficient and short-distance electrical connection between a terminal of each PV module and an ending of each metal wire of the support structure.

36. The flexible PV article according to claim 31,
wherein the support structure is a polymeric support substrate.

37. The flexible PV article according to claim 31,
wherein the support structure is a polymeric support substrate that is flexible and rollable.

38. The flexible PV article according to claim 31,
wherein the support structure is a polymeric support substrate that comprises:
a first polymeric support layer, that is generally planar;
a second polymeric support layer, that is generally planar, and that is generally parallel to the first polymeric support layer;
wherein the metal wires are integrally and non-removably sandwiched between the first polymeric support layer and the second polymeric support layer.

39. The flexible PV article according to claim 31,
wherein the polymeric support substrate comprises a foamed polymeric material that makes the polymeric support substrate lightweight and/or flexible and/or buoyant on water.

40. The flexible PV article according to claim 31,
wherein the polymeric support substrate comprises a polymeric base layer and a polymeric upper layer, that sandwich and conceal between them at least 50 percent of a length of each of the metal wires.

41. The flexible PV article according to claim 31,
wherein the polymeric support substrate comprises a polymeric base layer and a polymeric upper layer, that sandwich and conceal between them at least 50 percent of a cumulative total length of all the metal wires.

42. The flexible PV article according to claim 41,
wherein the polymeric base layer is formed of a first polymeric material having a first set of characteristics;
wherein the polymeric upper layer is formed of a second, different, polymeric material having a second, different, set of characteristics.

43. The flexible PV article according to claim 31,
wherein the polymeric support substrate, including the metal wires that are integrally embedded therein, is flexible and rollable;
wherein an entirety of the PV article, including the polymeric support substrate and the PV modules that are mounted thereon, is flexible and rollable.

44. The flexible PV article according to claim 31,
wherein the semiconductor wafer has non-transcending craters that penetrate into between 80 percent and 99 percent of a total thickness of the semiconductor wafer, and that do not penetrate into an entirety of the total thickness of the semiconductor wafer;
wherein said non-transcending craters in the semiconductor wafer increase flexibility and mechanical resilience and mechanical shock absorption of said PV cell.

45. The flexible PV article according to clam 31,
wherein the semiconductor wafer has non-transcending craters that penetrate into between 80 percent and 99 percent of a total thickness of the semiconductor wafer, and that do not penetrate into an entirety of the total thickness of the semiconductor wafer;
wherein at least some of said non-transcending craters contain a filler material having mechanical force absorption properties, which provides mechanical shock absorption properties to said PV cell.

46. A method of producing a support structure that is configured to support thereon one or more Photovoltaic (PV) modules, the method comprising:
producing a support structure, that has metal wires embedded integrally and internally therein,
wherein ending segments of the embedded metal wires protrude outwardly of the support structure at particular locations that are configured to match the locations of corresponding electrical terminals of PV modules that are intended to be mounted on top of said support structure.

47. The method according to claim 46,
wherein producing the support structure comprises:
producing a polymeric support substrate, that has metal wires embedded integrally and internally therein,
wherein ending segments of the embedded metal wires protrude outwardly of the polymeric support substrate at particular locations that are configured to match the locations of corresponding electrical terminals of PV modules that are intended to be mounted on top of said polymeric support substrate.

48. The method according to claim 47,
wherein producing the polymeric support substrate comprises:
producing a polymeric base layer that is generally planar;
placing a pre-defined wiring layout of metal wires on top of the polymeric base layer, wherein each metal wire is mostly on top of the polymeric base layer, wherein two short ending segments of each metal wire protrude out of the polymeric base layer;
placing a polymeric upper layer that is generally planar, on top of the wiring layout and on top of the polymeric base layer;
performing a heating and/or bonding process that integrally and non-removably embeds the wiring layout of metal wires as internally sandwiched component of the polymeric support substrate.
